(19) United States
(12) Patent Application Publication
(10) Pub. No.: US 2026/0247858 A1
(43) Pub. Date: Aug. 20, 2026

(54) COMPOSITION FOR ORGANIC ELECTROLUMINESCENT DEVICE, ORGANIC ELECTROLUMINESCENT DEVICE INCLUDING THE SAME, AND BORON-BASED COMPOUND

(71) Applicant: Samsung Electronics Co., Ltd., Suwon-si (KR)

(72) Inventors: Rie SAKURAI, Kanagawa (JP); Wataru SOTOYAMA, Kanagawa (JP); Satoshi INAYAMA, Kanagawa (JP); Eigo MIYAZAKI, Kanagawa (JP); Atsushi IMAMURA, Kanagawa (JP)

(21) Appl. No.: 19/536,588

(22) Filed: Feb. 11, 2026

(30) Foreign Application Priority Data
Feb. 18, 2025 (JP) 2025-023920
Nov. 19, 2025 (KR) 10-2025-0176092

(51) Int. Cl. H10K 85/60

(52) U.S. Cl. CPC H10K 85/6572; H10K 85/633

(57) ABSTRACT

A composition for an organic electroluminescent device, an organic electroluminescent device, and a compound of Formula 1. The composition includes the compound of Formula 1 and a phosphorescent material:

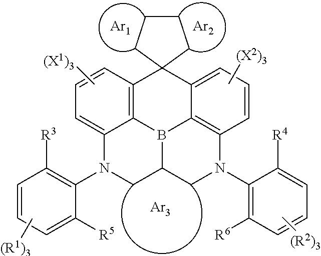

wherein, Ar₁, Ar₂, Ar₃, X¹, X², R¹, R², R³ and R⁴ in Formula 1, is described herein.

### CROSS-REFERENCE TO RELATED APPLICATIONS

This application claims priority to Japanese Patent Application No. JP2025-023920, filed on Feb. 18, 2025, in the Japan Patent Office, and Korean Patent Application No. 10-2025-0176092, filed on Nov. 19, 2025, in the Korean Intellectual Property Office, and all the benefits accruing therefrom under 35 U.S.C. § 119, the disclosures of which in their entirety are incorporated by reference herein.

### BACKGROUND

### 1. Field

The disclosure relates to a composition for an organic electroluminescent device, an organic electroluminescent device, and a boron-based compound.

### 2. Description of the Related Art

Organic electroluminescent devices are self-emissive devices that have wide viewing angles, high contrast ratios, short response times, and excellent characteristics in terms of luminance, driving voltage, and response speed, compared to devices in the art.

For instance, an organic electroluminescent device includes an anode, a cathode, and organic layers arranged between the anode and the cathode, one of which includes an emission layer. A hole transport region may be provided between the anode and the emission layer, and an electron transport region may be provided between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. When the excitons transition from an excited state to a ground state, light is emitted.

Organic electroluminescent devices may be adopted as displays for smartphones and the like, and efforts to improve color purity by utilizing the micro-cavity effect through a top-emission method have been attempted. This approach increases color purity, but has a drawback in that luminescence efficiency decreases.

At present, as a luminescent material for an organic electroluminescent device, a fluorescent material, a phosphorescent material, and the like are primarily used for light emission. Organic electroluminescent devices utilize three-color luminescent materials that emit red, green, and blue. Among these materials, there is continuing interest in the improvement of blue luminescent materials in terms of luminescence efficiency, device lifespan, color purity, and the like.

### SUMMARY

Provided is a novel composition for an organic electroluminescent device.

Additional aspects will be set forth in part in the description which follows and, in part, will be apparent from the description, or may be learned by practice of the presented embodiments of the disclosure.

According to an aspect of the disclosure, a composition for an organic electroluminescent device includes a compound represented by Formula 1 and a phosphorescent material:

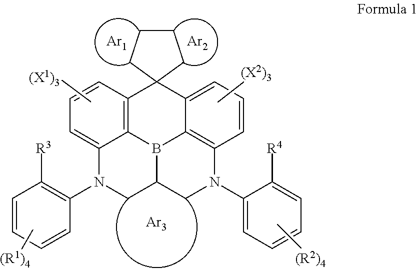

wherein, in Formula 1,
Ar₁, Ar₂, and Ars are each independently be a substituted or unsubstituted aryl group or a substituted or unsubstituted heteroaryl group,
X¹ and X² are each independently be hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group,
R¹ and R² are each independently be hydrogen, deuterium, a substituted or unsubstituted alkyl group, a substituted or unsubstituted aryl group, a substituted or unsubstituted heteroaryl group, or a substituted or unsubstituted cycloalkyl group, and
R³ and R⁴ are each independently be a substituted or unsubstituted alkyl group having at least three carbon atoms, a substituted or unsubstituted aryl group, a substituted or unsubstituted heteroaryl group, or a substituted or unsubstituted cycloalkyl group.

According to another aspect of the disclosure, provided is a compound represented by Formula 1.

According to another aspect of the disclosure, an organic electroluminescent device includes a first electrode, a second electrode, and an organic layer arranged between the first electrode and the second electrode, the organic layer including an emission layer, wherein the organic electroluminescent device includes the composition for an organic electroluminescent device including a compound represented by Formula 1 and a photoluminescence material.

According to another aspect of the disclosure, an electronic apparatus includes the organic electroluminescent device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an organic electroluminescent device according to an embodiment;

FIG. 2 is a schematic cross-sectional view of an organic electroluminescent device according to another embodiment; and

FIG. 3 is a schematic cross-sectional view of an organic electroluminescent device according to another embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Unless otherwise specified, operations and measurements of physical properties are performed at room temperature (20° C. to 25° C.)/relative humidity (RH) of 40% RH to 50% RH.

In the present specification, the expression “X and Y are each independently” indicates that X and Y may be identical to or different from each other.

Also, in the present specification, the “group derived from a ring refers to a group obtained by removing a hydrogen atom that is directly bonded to a ring-forming atom in a ring structure.

In the present specification, the number of ring-forming atoms refers to the number of atoms constituting a ring itself of a compound (e.g., a monocyclic compound, a condensed cyclic compound, a cross-linked compound, a carbocyclic compound, and a heterocyclic compound) having a structure in which atoms are bonded in a ring shape (e.g., monocyclic, condensed cyclic, and polycyclic). Atoms not substantially forming a ring (e.g., a hydrogen atom that terminates a bond of atoms forming a ring) or atoms included in a substituent when the ring is substituted with the substituent are not counted as the ring-forming atom. Unless otherwise specified, the number of ring-forming atoms described below is defined the same.

For example, the number of ring-forming atoms in an aromatic group (at times referred to as an aryl group) such as a benzene (or phenyl) ring is 6, the number of ring-forming atoms in a naphthalene (or naphthyl) ring is 10, the number of ring-forming atoms in a pyridine ring is 6, and the number of ring-forming atoms in a furan ring is 5.

When a benzene ring is substituted with, for example, an alkyl group as a substituent, the number of carbon atoms in the alkyl group is not counted as the number of ring-forming atoms in the benzene ring. In this regard, the number of ring-forming atoms in the benzene ring substituted with the alkyl group is 6. Also, when a naphthalene ring is substituted with, for example, an alkyl group as a substituent, the number of atoms in the alkyl group is not counted as the number of ring-forming atoms in the naphthalene ring. In this regard, the number of ring-forming atoms in the naphthalene ring substituted with the alkyl group is 10. For example, a hydrogen atom bonded to a pyridine ring or atoms constituting a substituent is not counted as the number of ring-forming atoms in the pyridine ring. In this regard, the number of ring-forming atoms in the pyridine ring to which the hydrogen atom or the substituent is bonded is 6.

Examples of an aromatic hydrocarbon ring of which the number of ring-forming atoms is 6 to 30 include, although not particularly limited thereto, a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a phenyl ring, a biphenyl ring, a triphenylene ring, a pyrene ring, a chrysene ring, a picene ring, a perylene ring, a pentaphene ring, a pentacene ring, a tetraphene ring, a hexacene ring, a rubicene ring, a trinaphthylene ring, a heptaphene ring, a pyranthrene ring and the like.

A heteroaromatic ring (at times referred to as heteroaryl group) includes at least one heteroatom as a ring-forming atom (e.g., a nitrogen atom (N), an oxygen atom (O), a phosphorus atom (P), a sulfur atom(S), and a silicon atom (Si)) and carbon atoms (C) as the remaining ring-forming atoms. Specific examples of a heteroaromatic ring of which the number of ring-forming atoms is 3 to 30 include, although not particularly limited thereto, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzo ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, a benzimidazole ring, a pyrazole ring, an indazole ring, an oxazole ring, an isoxazole ring, a benzoxazole ring, a benzoisoxazole ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazophenanthridine ring, a benzimidazophenanthridine ring, an azadibenzofuran ring, an azacarbazole ring, an azadibenzothiophene ring, a diazadibenzofuran ring, a diazadibenzothiophene ring, a diazacarbazole ring, a xanthone ring, a thioxane ring, and the like.

In the present specification, the aryl group may be, although not particularly limited thereto, for example, a monovalent group derived from at least one aromatic hydrocarbon ring. Also, the hydrocarbon ring constituting the aryl group may be a condensed ring. When the aryl group includes two or more aromatic hydrocarbon rings, the two or more aromatic hydrocarbon rings may be bonded to each other via a single bond (in the form of a polycyclic aromatic hydrocarbon ring). The number of ring-forming atoms in the aryl group may be, although not particularly limited thereto, 6 to 30. Furthermore, the number of ring-forming atoms in the aryl group may be 6 to 20 and 6 to 18. Specific examples of the aryl group include, although not particularly limited thereto, a phenyl group, a naphthyl group, a phenanthryl group, a biphenylenyl group, a triphenylene group, an anthryl group, a pyrenyl group, a fluorenyl group, an azulenyl group, an acenaphthenyl group, a fluorantenyl group, a naphthacenyl group, a perylenyl group, a pentacenyl group, a quaterphenyl group, a chrycenyl group, and the like.

In the present specification, the heteroaryl group may be, although not particularly limited thereto, for example, a monovalent group derived from a ring including at least one aromatic heteroatom that includes at least one heteroatom (e.g., N, O, P, S, Si, etc.) as the ring-forming atom and C as the remaining ring-forming atoms. When two or more heteroatoms are included, the two or more heteroatoms may be identical to or different from each other. Furthermore, the ring constituting the heteroaryl group may be a condensed ring. In addition, when the heteroaryl group includes two or more aromatic hetero rings, the two or more aromatic hetero rings may be bonded to each other via a single bond.

As such, the heteroaryl group may be a monocyclic heteroaryl group or a polycyclic heteroaryl group. The number of ring-forming atoms in the heteroaryl group may be, although not particularly limited thereto, 3 to 30. Also, the number of ring-forming atoms in the heteroaryl group may be 3 to 20 or 3 to 18. Specific examples of the heteroaryl group include, although not particularly limited thereto, a thienyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, a triazolyl group, an acridinyl group, a pyridazinyl group, a pyridinyl group, a quinolinyl group, a quinazolinyl group, a quinoxalinyl group, a phenoxazinyl group, a phthalazinyl group, a pyridopyrimidinyl group, a pyridopyrazinyl group, a pyrazinopyradinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzimidazolyl group, a benzothiazolyl group, a benzocarbazolyl group, a benzothiophenyl group, a dibenzothiophenyl group, a thienothienyl group, a benzofuranyl group, a phenanthrolinyl group, an isoxazolyl group, a thiadiazolyl group, a phenothiazinyl group, a dibenzosilolyl group, a dibenzofuranyl group, and the like.

In the present specification, examples of the halogen atom include a fluorine atom (F), a chlorine atom (CI), a bromine atom (Br), an iodine atom (I), and the like.

In the present specification, the alkyl group may be linear, branched, or cyclic. The number of carbon atoms in the alkyl group may be, although not limited thereto, 1 to 30 and 1 to 20. Furthermore, the number of carbon atoms in the alkyl group may be 1 to 10 and 1 to 6. Specific examples of the alkyl group include, although not limited thereto, a methyl group, an ethyl group, an n-propyl group, an isopropyl group, an n-butyl group, a sec-butyl group, a tert-butyl group, an isobutyl group, a 2-ethylbutyl group, a 3,3-dimethylbutyl group, an n-pentyl group, an isopentyl group, a neopentyl group, a tert-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-tert-butylcyclohexyl group, an n-heptyl group, a 1-methylheptyl group, a 2,2-dimethylheptyl group, a 2-ethylheptyl group, a 2-butylheptyl group, an n-octyl group, a tert-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like.

In the present specification, the alkenyl group has a structure including at least one carbon-carbon double bond in the middle or at the terminus of the alkyl group, and examples thereof include an ethenyl group, a propenyl group, a butenyl group, and the like.

In the present specification, the alkynyl group has a structure including at least one carbon-carbon triple bonds in the middle or at the terminus of the alkyl group, and examples thereof include an ethynyl group, a propynyl group, and the like.

In the present specification, the alkoxy group may be linear, branched, or cyclic. The alkyl group constituting the alkoxy group may be, although not limited thereto, for example, the same as described in the connection with the alkyl group described as a substituent. The number of carbon atoms in the alkoxy group may be, although not limited thereto, 1 or more. Also, the number of carbon atoms in the alkoxy group may be 20 or less, 10 or less, and 4 or less. Specific examples of the alkoxy group include, although not limited thereto, a methoxy group, an ethoxy group, an n-propyloxy group, an isopropyloxy group, an n-butyloxy group, a sec-butyloxy group, a tert-butyloxy group, an isobutyloxy group, a 2-ethylbutyloxy group, a 3,3-dimethylbutyloxy group, an n-pentyloxy group, an isopentyloxy group, a neopentyloxy group, a tert-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a cyclohexyloxy group, a 4-methylcyclohexyloxy group, a 4-tert-butylcyclohexyloxy group, an n-heptyloxy group, a 1-methylheptyloxy group, a 2,2-dimethylheptyloxy group, a 2-ethylheptyloxy group, a 2-butylheptyloxy group, an n-octyloxy group, a tert-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, an adamantyloxy group, and the like.

In the present specification, the aryloxy group is not particularly limited. The number of carbon atoms in the aryloxy group may be, although not limited thereto, 6 to 30. The number of carbon atoms in the aryloxy group may be 6 to 12, and may be 6. Specific examples of the aryloxy group include, although not limited thereto, a phenyloxy group, a biphenyloxy group, a terphenyloxy group, a naphthyloxy group, a fluorenyloxy group, an anthracenyloxy group, a quarterterphenyloxy group, a quinquephenyloxy group, a triphenylenyloxy group, a pyrenyloxy group, a benzofluolenyloxy group, a chrysenyloxy group, and a combination thereof.

In the present specification, the heteroaryloxy group is not particularly limited. The heteroaryl group constituting the heteroaryloxy group may be, although not limited thereto, for example, the same as described in the description of the heteroaryl group. The number of ring-forming atoms in the heteroaryloxy group may be, although not particularly limited thereto, 3 to 30. Furthermore, the number of ring-forming atoms in the heteroaryloxy group may be 3 to 14 and 3 to 13. The number of heteroatoms as the ring-forming atoms in the heteroaryloxy group may be, although not particularly limited thereto, 1 to 3. Furthermore, the number of heteroatoms as the ring-forming atoms in the heteroaryloxy group may be 1 to 2, and may be 1. Specific examples of the heteroaryloxy group include, although not limited thereto, a thienyloxy group, a furanyloxy group, a pyrrolyloxy group, an imidazolyloxy group, a thiazolyloxy group, an oxazolyloxy group, an oxadiazolyloxy group, a trizaolyloxy group, a pyridyloxy group, a bipyridyloxy group, a pyrimidyloxy group, a triazinyloxy group, a triazolyloxy group, an acridinyloxy group, a pyridazinyloxy group, a pyridinyloxy group, a quinolinyloxy group, a quinazolinyloxy group, a quinoxalinyloxy group, a phenoxazinyloxy group, a phthalazinyloxy group, a pyridopyrimidinyloxy group, a pyridopyrazinyloxy group, a pyrazinopyrazinyloxy group, an isoquinolinyloxy group, an indolyloxy group, a carbazolyloxy group, a benzoxazolyloxy group, a benzimidazolyloxy group, a benzothiazolyloxy group, a benzocarbazolyloxy group, a benzothiophenyloxy group, a dibenzothienyloxy group, a thienothienyloxy group, a benzofuranyloxy group, a phenanthrolinyloxy group, a thiazolyloxy group, an isoxazolyloxy group, an oxadiazolyloxy group, a thiadiazolyloxy group, a phenothiazinyloxy group, a dibenzosilolyloxy group, a dibenzofuranyloxy group, a xanthonyloxy group, and a combination thereof.

In the present specification, the diarylamino group, the diheteroarylamino group, and the arylheteroarylamino group are not particularly limited. Examples of the aryl group and hetero group that constitute the diarylamino group, diheteroarylamino group, and arylheteroarylamino group include those described in the respective descriptions of the aryl group and heteroaryl group. Specific examples of the diarylamino group include, although not limited thereto, a diphenylamino group, a bis(4-tert-butylphenyl)amino group, a phenyl(naphthyl)amino group, a di(biphenyl)amino group, a di(p-terphenyl)amino group, and the like. Specific examples of the arylheteroarylamino group include, although not limited thereto, a phenyl(2-pyridyl)amino group and the like. Specific examples of the diheteroarylamino group include, although not limited thereto, a di(2-pyridyl)amino group and the like.

In the present specification, the cycloalkyl group is not particularly limited. The number of carbon atoms in the cycloalkyl group may be, for example, 3 to 18, specifically, 3 to 12, and more specifically, 3 to 6. Specific examples of the cycloalkyl group include a cyclopropyl group, a cyclobutyl group, a cyclopentyl group, a cyclohexyl group, and the like.

In the present specification, the heterocycloalkyl group refers to a ring group further including, as a ring-forming atom, at least one heteroatom selected from N, O, P, Si, and S, and examples thereof include a tetrahydrofuranyl group, a tetrahydrothiophenyl group, and the like.

In the present specification, the arylthio group is not particularly limited. Specific examples of the arylthio group include a phenylthio group, a biphenylthio group, a terphenylthio group, a naphthylthio group, a fluorenylthio group, an anthracenylthio group, a terphenylthio group, a quarterphenylthio group, a quinquephenylthio group, a triphenylenylthio group, a pyrenylthio group, a benzofluorenylthio group, a chrysenylthio group, and the like.

In the present specification, the heteroarylthio group is not particularly limited. Specific examples of the heteroarylthio group include a thienylthio group, a furanylthio group, a pyrrolylthio group, an imidazolylthio group, a thiazolylthio group, an oxazolylthio group, an oxadiazolylthio group, a triazolylthio group, a pyridylthio group, a bipyridylthio group, a pyrimidylthio group, a triazinylthio group, a triazolylthio group, an acridinylthio group, a pyridazinylthio group, a pyridinylthio group, a quinolinylthio group, a quinazolinylthio group, a quinoxalinylthio group, a phenoxazinylthio group, a phthalazinylthio group, a pyridopyrimidinylthio group, a pyridopyrazinylthio group, a pyrazinopyrazinylthio group, an isoquinolinylthio group, an indolylthio group, a carbazolylthio group, a benzoxazolylthio group, a benzimidazolylthio group, a benzothiazolylthio group, a benzocarbazolylthio group, a benzothiophenylthio group, a dibenzothiophenylthio group, a thienothiophenylthio group, a benzofuranylthio group, a phenanthrolinylthio group, a thiazolylthio group, an isoxazolylthio group, an oxadiazolylthio group, a thiadiazolylthio group, a phenothiazinylthio group, a dibenzosilolylthio group, a dibenzofuranylthio group, a xanthonylthio group, and the like.

In the present specification, types of substituents are not particularly limited, but may include, for example, a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, a substituted or unsubstituted arylheteroarylamino group, and the like. When two or more hydrogen atoms are substituted, the types of substituents may be identical to or different from each other.

### Composition for Organic Electroluminescent Device

According to an aspect of the disclosure, a composition for an organic electroluminescent device includes a compound represented by Formula 1 and a phosphorescent material:

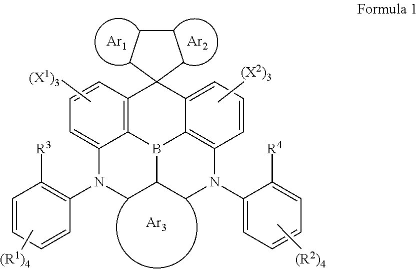

wherein, in Formula 1,
Ar₁, Ar₂, and Ars are each independently be a substituted or unsubstituted aryl group or a substituted or unsubstituted heteroaryl group,
X¹ and X² are each independently be hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group,
R¹ and R² are each independently be hydrogen, deuterium, a substituted or unsubstituted alkyl group, a substituted or unsubstituted aryl group, a substituted or unsubstituted heteroaryl group, or a substituted or unsubstituted cycloalkyl group, and
R³ and R⁴ are each independently be a substituted or unsubstituted alkyl group having at least three carbon atoms, a substituted or unsubstituted aryl group, a substituted or unsubstituted heteroaryl group, or a substituted or unsubstituted cycloalkyl group.

The composition for an organic electroluminescent device may improve luminescence efficiency and device lifespan of an organic electroluminescent device.

Recently, it has been reported that luminescent materials, such as the following compound into which a boron atom has been introduced, exhibited blue luminescence and demonstrated a narrow half-width at half maximum and relatively high luminescence efficiency in an organic electroluminescent device:

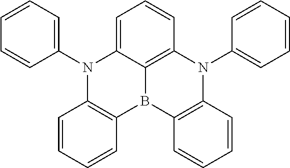 [SMILES: c1ccc(N2c3ccccc3B3c4ccccc4N(c4ccccc4)c4cccc2c43)cc1]

However, an organic electroluminescent device using such a compound exhibits low luminescence efficiency and/or short lifespan yet, requiring further improvements for commercialization.

For the energy transfer process from a host molecule to a guest molecule (e.g., a luminescent material) in an emission layer of an organic electroluminescent device, Dexter energy transfer or Förster energy transfer is known. In Förster energy transfer, when the host molecule becomes excited, a neighboring luminescent material may form an excited singlet state, emit light, and then return to the ground singlet state. Meanwhile, when Dexter energy transfer occurs, the luminescent material enters an excited triplet state, but this state does not contribute to light emission. The luminescent material returns to the ground singlet state after undergoing thermal deactivation. Spin inversion is required to return from this excited triplet state to the ground state, and thus it takes longer to deactivate than the excited singlet state. Therefore, such an unstable high-energy state is more susceptible to chemical reactions, the consequence of which may result in degradation in device performance. Therefore, to achieve high efficiency and long lifespan of an organic electroluminescent device, it is necessary to suppress Dexter energy transfer. The potential for Dexter energy transfer depends on intermolecular distance, and one way to suppress the Dexter energy transfer is to increase the intermolecular distance (also referred to as proximity suppression).

The inventors of the disclosure discovered that, by introducing bulky substituents into molecules to suppress Dexter energy transfer, the intermolecular distance between a phosphorescent material (e.g., a phosphorescent complex or a sensitizer) and a compound to which a boron atom has been introduced could be increased, thereby improving the luminescence efficiency of the device.

Specifically, in the compound represented by Formula 1, substituent portions labeled A and B below correspond to bulky substituents as shown in Formula 1′. When bulky substituents are introduced into R³ and R⁴ in the substituent portions labeled B, the compound forms, to avoid steric repulsion, a linear structure with the substituent portions labeled B perpendicular to a boron-containing portion of the compound (i.e., the portion other than those labeled A and B). In this regard, the compound represented by Formula 1 may increase in volume resulting in proximity suppression between the phosphorescent material and the boron-containing portion of the compound. Furthermore, the substituent portion labeled A also forms a linear structure perpendicular to the compound to which a boron atom has been introduced, thereby contributing to increasing the overall molecular volume. Accordingly, it is considered that the composition for an organic electroluminescent device of the disclosure may improve luminescence efficiency and lifespan of an organic electroluminescent device including the composition.

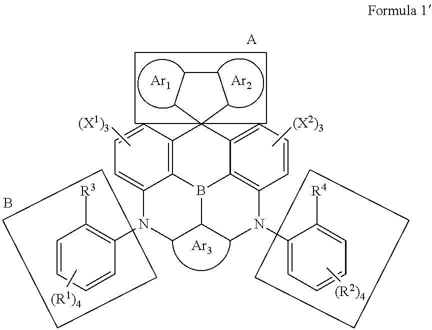

This mechanism described above is provided only to explain how the composition described herein provides the optical advantages and performance observed by the inventors, and in no way be used to narrow the claimed subject matter or in no way affect the technical scope of the invention.

Hereinafter, materials for an organic electroluminescent device of the disclosure will be described in detail.

### Compound Represented by Formula 1)

The composition for an organic electroluminescent device of the disclosure includes the compound represented by Formula 1:

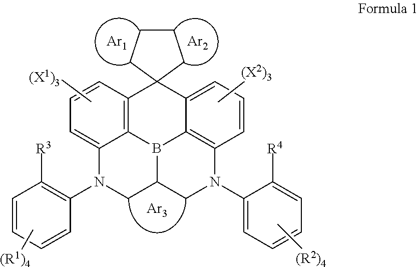

wherein, in Formula 1,
Ar₁, Ar₂, and Ars are each independently be a substituted or unsubstituted aryl group or a substituted or unsubstituted heteroaryl group.

In Formula 1, Ar₁, Ar₂, and Ars are each independently be a substituted or unsubstituted aryl group. In an embodiment, Ar₁ and Ar₂ may be specifically an unsubstituted aryl group, and more specifically an unsubstituted phenyl group. In an embodiment, Ars may be an unsubstituted phenyl group. When Ars is substituted with a substituent, the substituent may be a substituted or unsubstituted alkyl group, a substituted or unsubstituted aryl group, or a substituted or unsubstituted heteroaryl group. In an embodiment, the substituent may be an unsubstituted alkyl group, a substituted aryl group, or an unsubstituted heteroaryl group. In another embodiment, the substituent may be an unsubstituted alkyl group having 1 to 6 carbon atoms, a substituted aryl group having 6 to 18 ring-forming atoms, or an unsubstituted heteroaryl group having 5 to 18 ring-forming atoms. In another embodiment, the substituent may be a tert-butyl group, a 3,5-di(tert-butyl) phenyl group, a carbazolyl group, a phenyl group, or a 4-tert-butylphenyl group.

In Formula 1, X¹ and X² are each independently be hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group.

In Formula 1, X¹ and X² are each independently be specifically hydrogen, an unsubstituted alkyl group, an unsubstituted aryl group, or an unsubstituted heteroaryl group, more specifically hydrogen, an unsubstituted alkyl group having 1 to 6 carbon atoms, an unsubstituted aryl group having 6 to 18 ring-forming atoms, or an unsubstituted heteroaryl group having 5 to 18 ring-forming atoms, and even more specifically hydrogen, a tert-butyl group, a phenyl group, a carbazolyl group, a 4-tert-butylphenyl group, or a 3,5-di(tert-butyl)phenyl group.

In Formula 1, R¹ and R² are each independently be hydrogen, deuterium, a substituted or unsubstituted alkyl group, a substituted or unsubstituted aryl group, a substituted or unsubstituted heteroaryl group, or a substituted or unsubstituted cycloalkyl group.

In Formula 1, R¹ and R² are each independently be specifically hydrogen, deuterium, an unsubstituted alkyl group, or an unsubstituted aryl group, more specifically an unsubstituted alkyl group having 3 to 6 carbon atoms or an unsubstituted aryl group having 6 to 18 ring-forming atoms, and even more specifically hydrogen, a tert-butyl group, an isopropyl group, or a phenyl group.

In Formula 1, R³ and R⁴ are each independently be a substituted or unsubstituted alkyl group having at least three carbon atoms, a substituted or unsubstituted aryl group, a substituted or unsubstituted heteroaryl group, or a substituted or unsubstituted cycloalkyl group.

Regarding R³ and R⁴, the alkyl group having at least three carbon atoms may be either a linear alkyl group or a branched alkyl group. The number of carbon atoms in the alkyl group is not particularly limited as long as it is 3 or more, but may be, for example, in a range of 3 to 30, specifically 3 to 20, more specifically 3 to 10, and even more specifically 3 to 6.

In Formula 1, R³ and R⁴ are each independently be specifically an unsubstituted alkyl group having at least three carbon atoms, a substituted or unsubstituted aryl group, or an unsubstituted cycloalkyl group, more specifically an unsubstituted alkyl group having 3 to 6 carbon atoms, a substituted or unsubstituted aryl group having 6 to 18 ring-forming atoms, or an unsubstituted cycloalkyl group having 3 to 6 carbon atoms, and even more specifically an isopropyl group, a tert-butyl group, a phenyl group, a substituted phenyl group, or a cyclohexyl group. When R³ and R⁴ are substituted with a substituent, the substituent may specifically be an unsubstituted aryl group or an unsubstituted cycloalkyl group, more specifically an unsubstituted aryl group having 6 to 18 ring-forming atoms, or an unsubstituted cycloalkyl group having 3 to 6 carbon atoms, and even more specifically, a phenyl group or a cyclohexyl group.

Regarding the materials for an organic electroluminescent device of the disclosure, the compound of Formula 1 may be a compound represented by Formula 2:

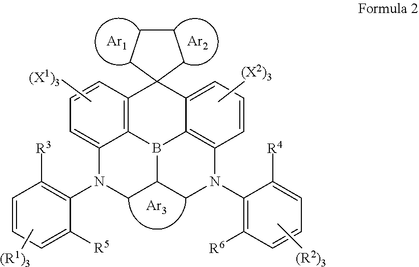

wherein, in Formula 2,
R⁵ and R⁶ are each independently be a substituted or unsubstituted alkyl group having at least three carbon atoms, a substituted or unsubstituted aryl group, a substituted or unsubstituted heteroaryl group, or a substituted or unsubstituted cycloalkyl group, and
Ar₁, Ar₂, Ar₃, X¹, X², R¹, R², R³, and R⁴ may be the same as those described in connection with Formula 1.

By introducing bulky substituents into not only R³ and R⁴ but also R⁵ and R⁶, the compound represented by Formula 2 may suppress the proximity between the phosphorescent material and the compound of Formula 2.

Regarding R⁵ and R⁶, the alkyl group having at least three carbon atoms, an aryl group, an heteroaryl group, or a cycloalkyl group may each be the same as those described above.

Regarding R⁵ and R⁶, at least one hydrogen in the alkyl group having at least three carbon atoms, the aryl group, the heteroaryl group, or the cycloalkyl group may be substituted with a substituent. Here, types of substituents may be the same as those described above.

In Formula 2, R⁵ and R⁶ are each independently be an unsubstituted alkyl group having at least three carbon atoms or an unsubstituted alkyl group, more specifically, an unsubstituted alkyl group having 3 to 6 carbon atoms, or an unsubstituted aryl group having 6 to 18 ring-forming atoms, for example, a tert-butyl group or a phenyl group.

In an embodiment, the compound represented by Formula 1 may be selected from Group I, but is not limited thereto:

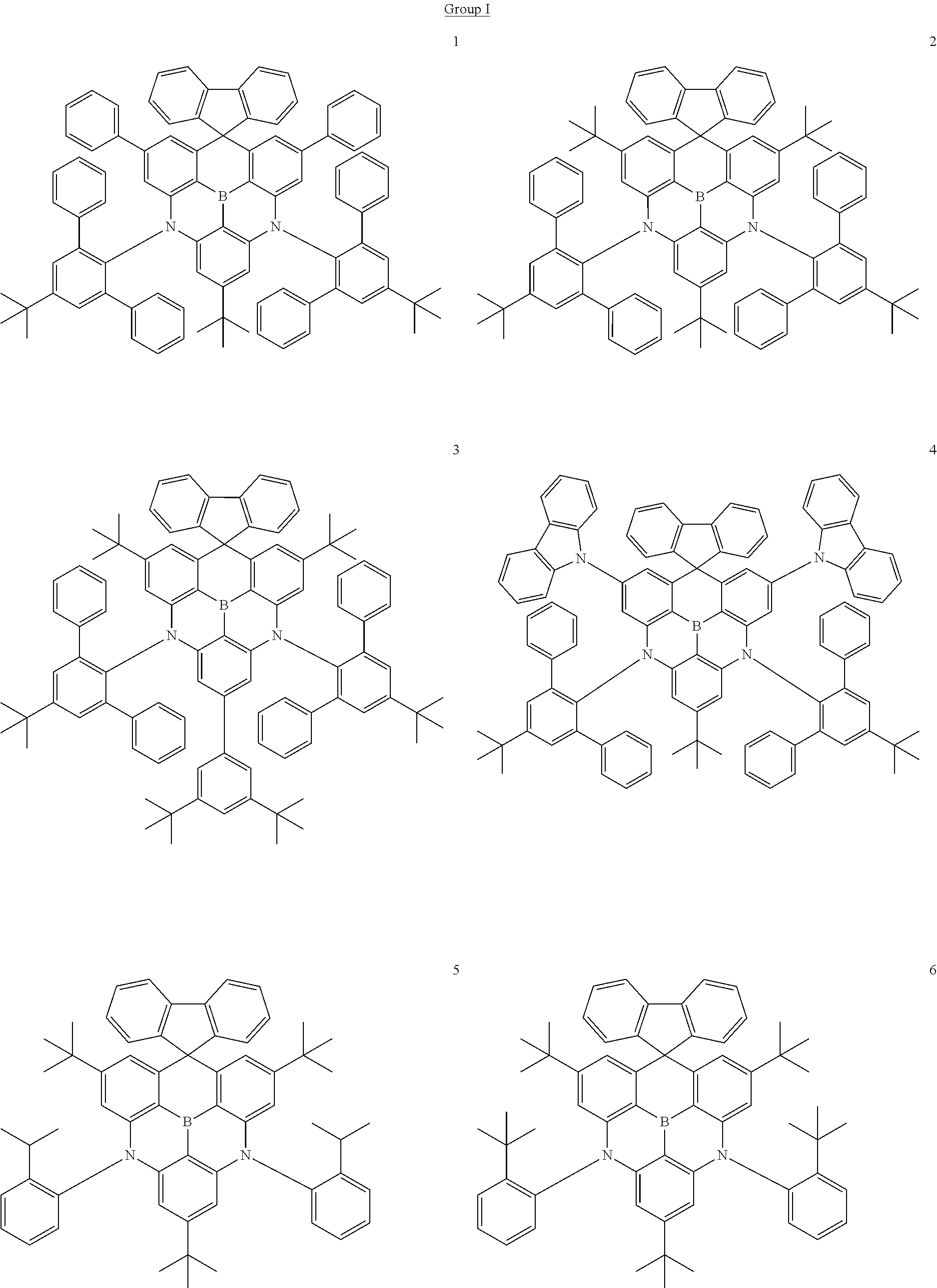

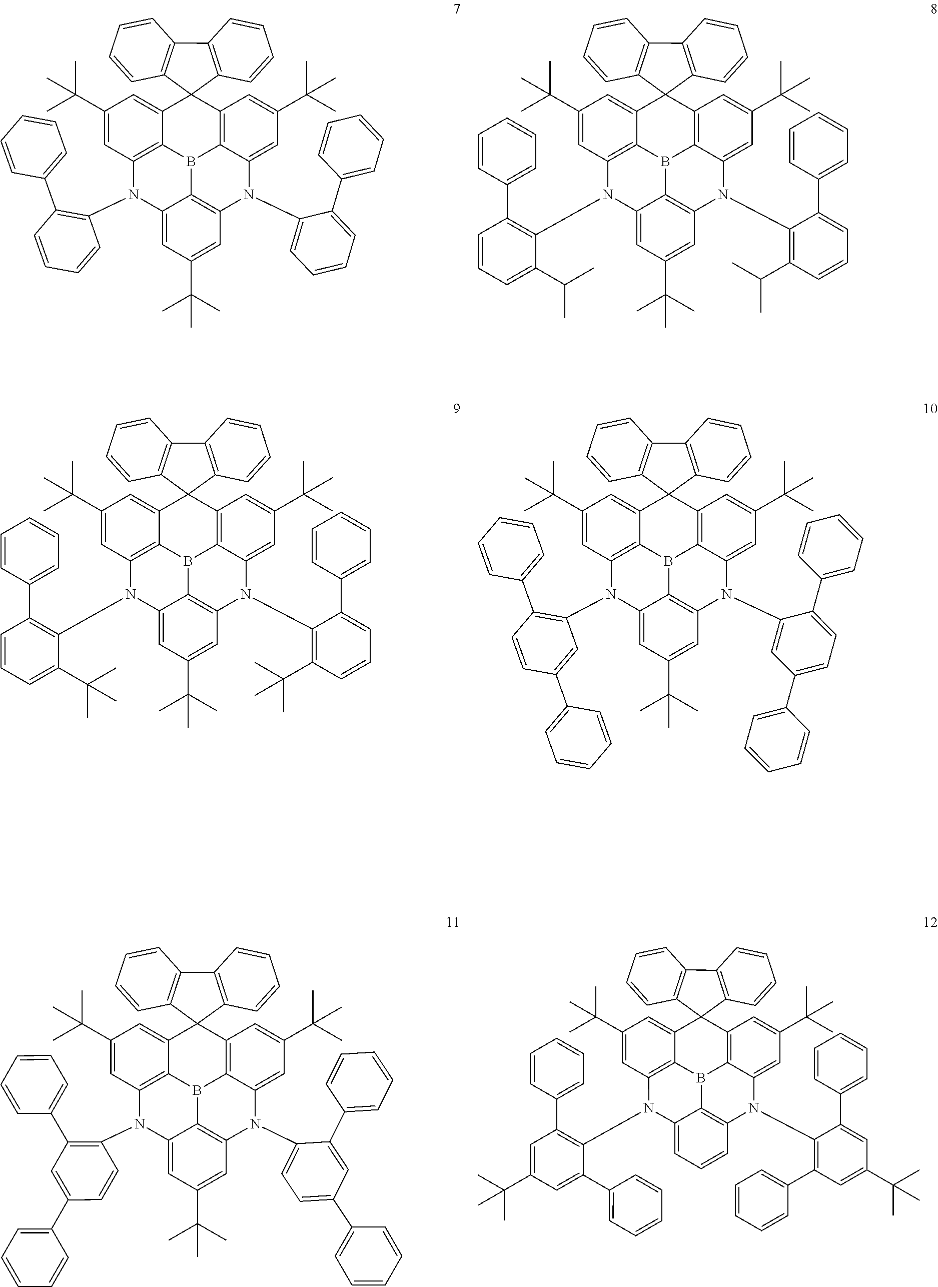

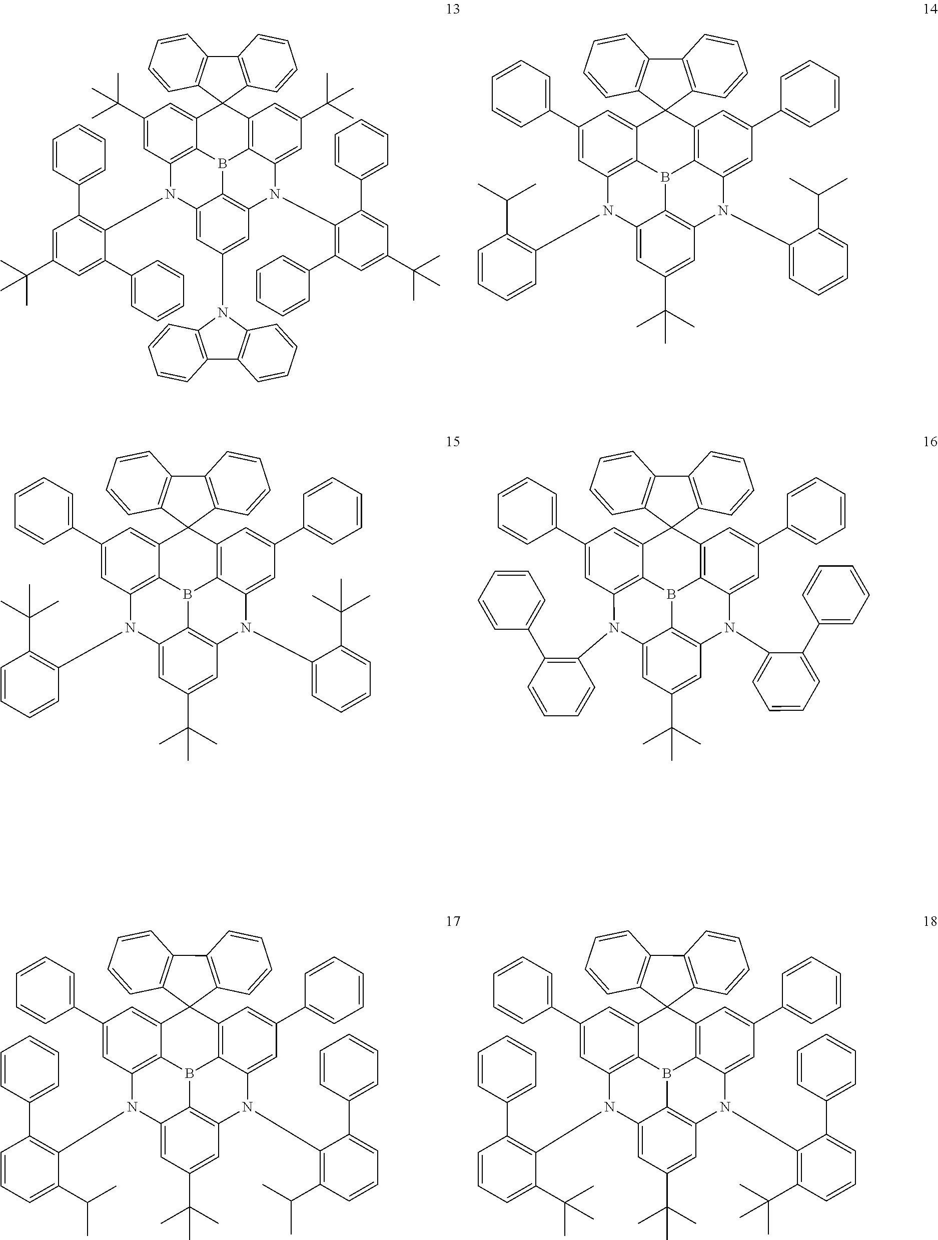

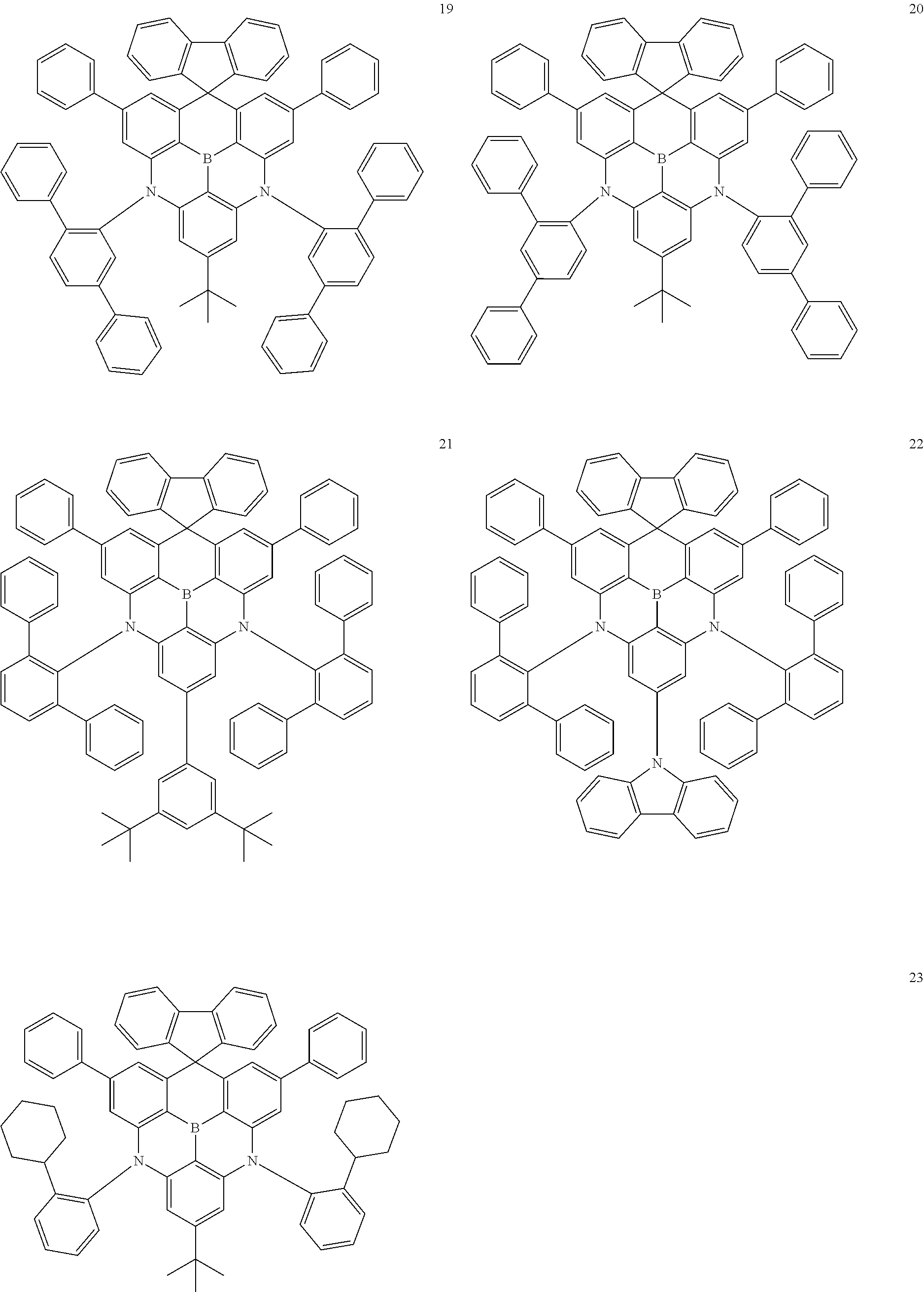

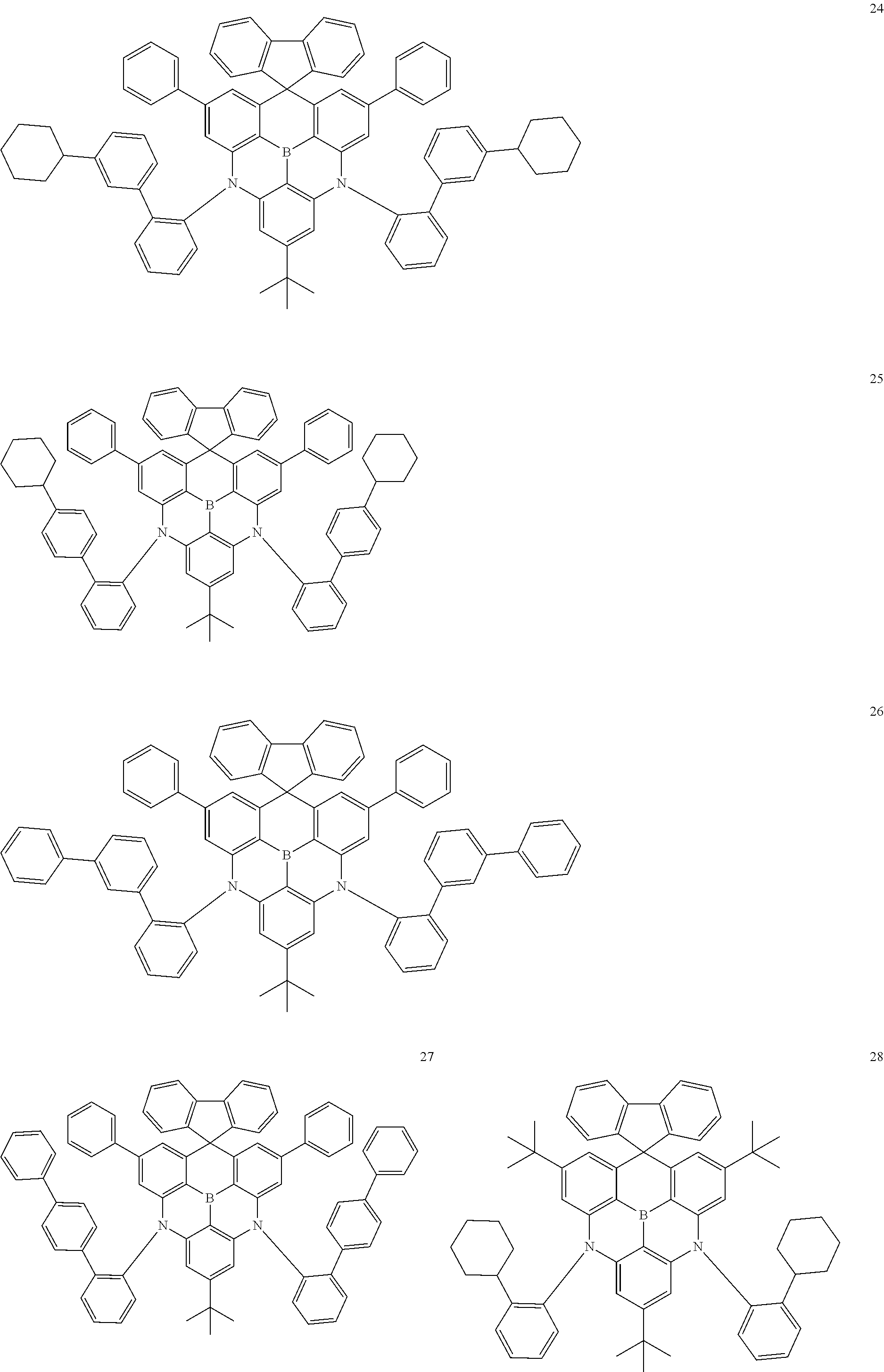

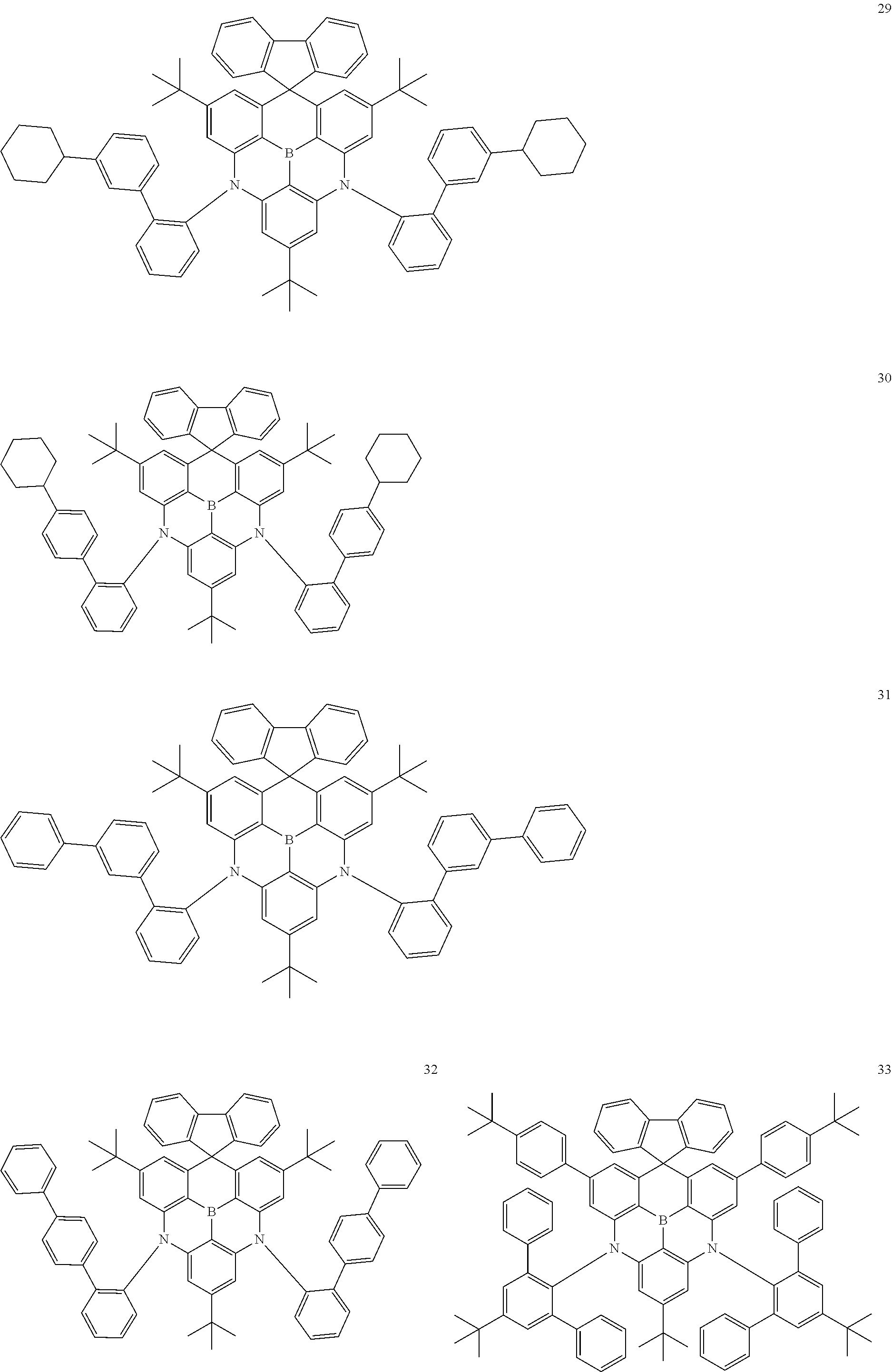

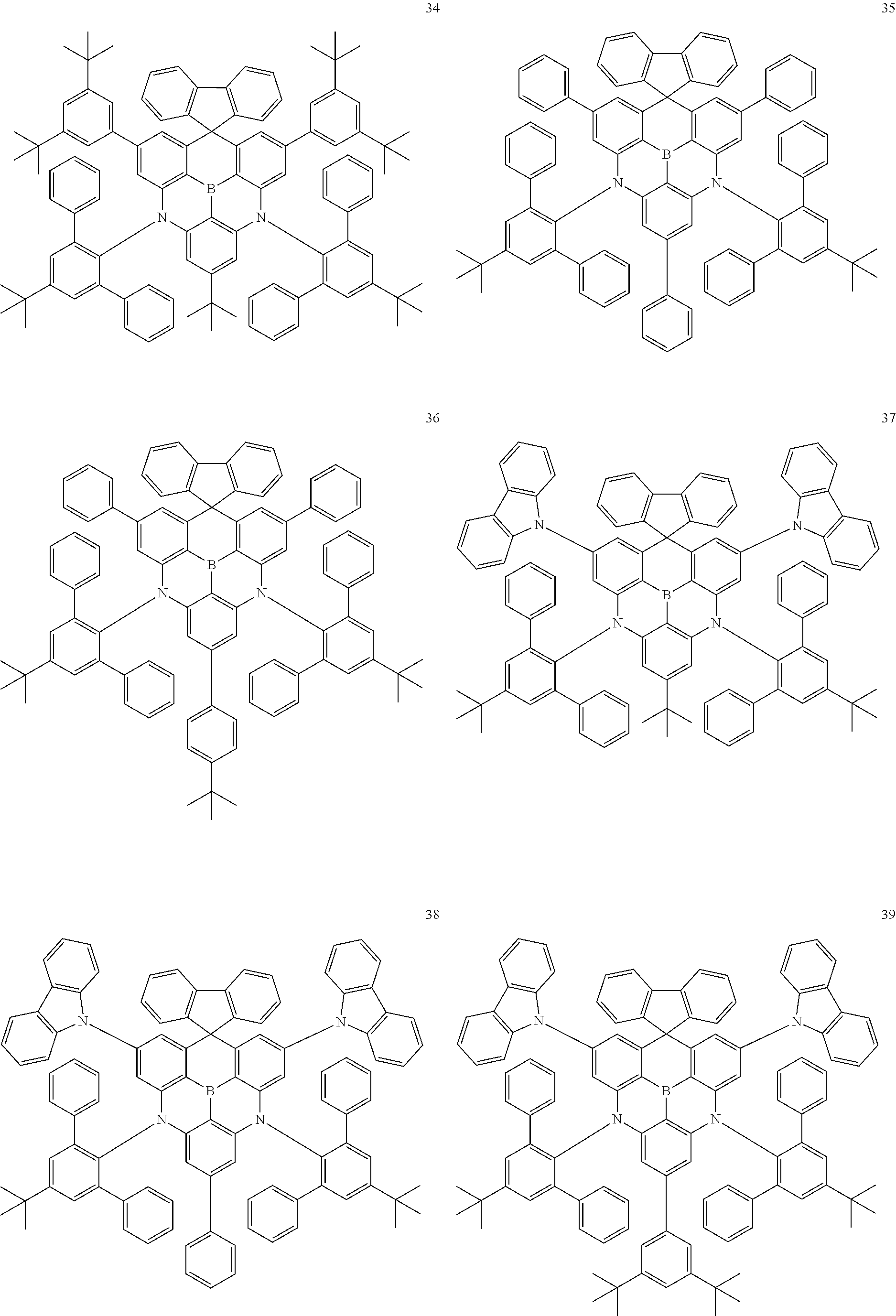

In an embodiment, the compound represented by Formula 1 may be selected from Compounds 1 to 4, e.g., may be Compound 1.

In the compound of Formula 1, peak wavelengths of fluorescence in the photoluminescence (PL) is not particularly limited. These peak wavelengths may be within the blue wavelength region. These peak wavelengths may be, for example, in a range of about 360 nm to about 515 nm, about 420 nm to about 490 nm, about 430 nm to about 480 nm, or about 450 nm to about 470 nm. The peak wavelength of luminescence in PL may be measured, e.g. with a F-7000 spectrophotometer Hitach High-Tech, Ltd. More specifically, a 1×10⁻⁵ M (mol/dm³, mol/L) toluene solution of the compound of Formula 1 or Formula 2 may be evaluated by measuring at room temperature using a spectrofluorometer with an excitation wavelength of 300 nm, or a thin film formed by co-depositing the compound represented by Formula 1 or Formula 2 and a host according to methods described in Examples below may be evaluated by measuring at room temperature using a spectrofluorometer with an excitation wavelength of 300 nm.

The compound of Formula 1 or Formula 2 may be synthesized by methods described in Examples below or methods in accordance with methods described in Examples.

The compound of Formula 1 or Formula 2 may be synthesized based on the following reaction scheme. In the following reaction scheme, the compound having the structure reaction Formula 2 is used as an example, and R¹, R², X¹, and X² are omitted.

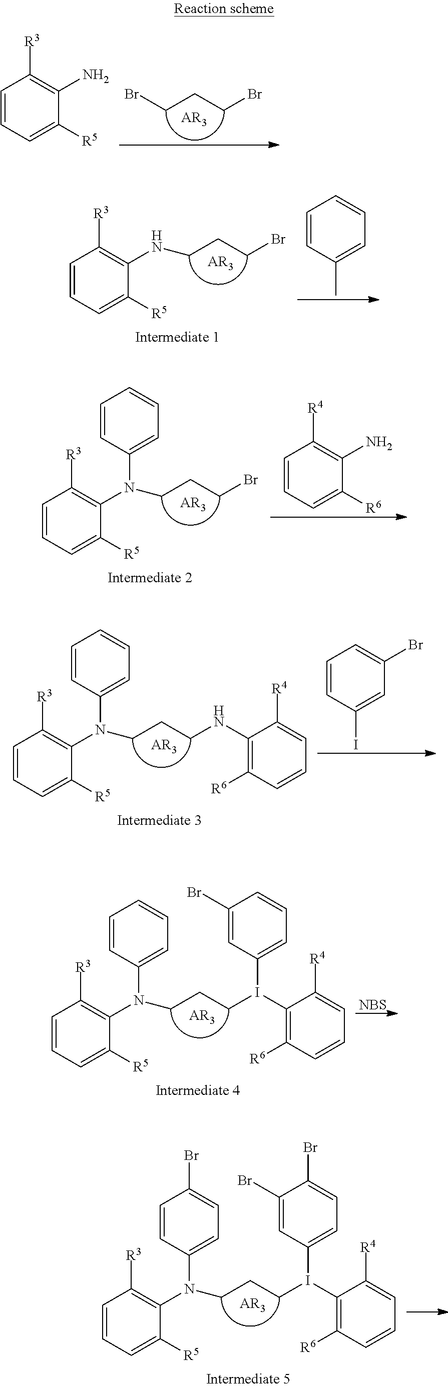

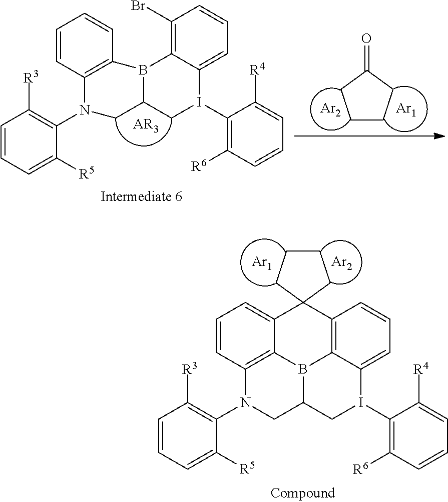

In the reaction scheme, Intermediates 1 to 6 and compounds may be obtained using known reactions such as Buchwald-Hartwig amination and intramolecular cyclization reactions. Materials used for synthesizing each intermediate and compound may be obtained using methods known in the art.

More specifically, the compounds may be synthesized by, for example, methods described in Examples below.

Methods of identifying the structure of the compound of Formula 1 are not particularly limited. The structure of the compound of Formula 1 may be identified by, for example, using methods known in the art (e.g., NMR, LC-MS, etc.).

### Phosphorescent Material

The material for an organic electroluminescent device of the disclosure may include a phosphorescent material. The phosphorescent material (e.g., a phosphorescent compound) is not particularly limited, and may utilize a known compound exhibiting phosphorescence. The phosphorescent material may be a phosphorescent complex, an iridium complex, or a platinum complex. In particular, the phosphorescent material may be a platinum complex.

In an embodiment, the phosphorescent material may include an organic ligand (L₁₁) and at least one metal (M₁₁) selected from a fourth-row transition metal, a fifth-row transition metal, a sixth-row transition metal, and a seventh-row transition metal of the Periodic Table of Elements, wherein L₁₁ and M₁₁ may form one, two, three, or four cyclometallated rings.

In an embodiment, the phosphorescent material may include a phosphorescent complex represented by Formula 101:

M₁₁(L₁₁)ₙ₁₁(L₁₂)ₙ₁₂ Formula 101
wherein, in Formula 101,
M₁₁ may be a fourth-row transition metal, a fifth-row transition metal, a sixth-row transition metal, and a seventh-row transition metal of the Periodic Table of Elements,
L₁₁ may be a ligand represented by one of Formulae 1-1 to 1-4,
L₁₂ may be selected from a monodentate ligand and a bidentate ligand,
n11 may be 1, and
n12 may be selected from 0, 1, and 2:

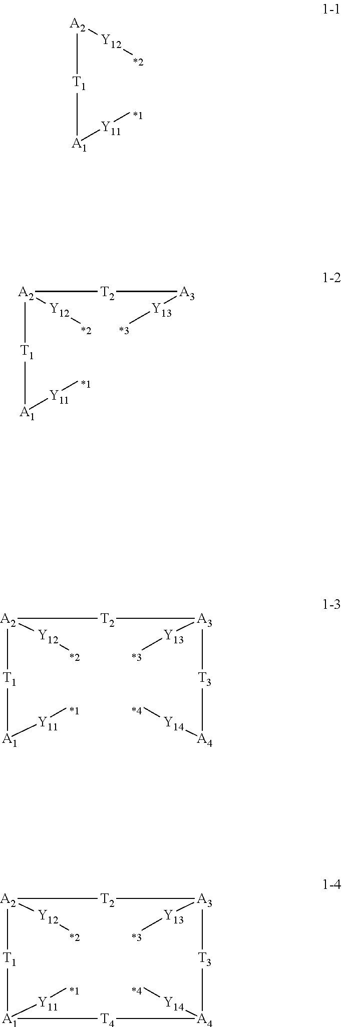

wherein, in Formulae 1-1 to 1-4,
A₁ to A₄ may each independently be selected from a substituted or unsubstituted carbocyclic group, a substituted or unsubstituted heterocyclic group, and a non-cyclic group,
Y₁₁ to Y₁₄ may each independently be a chemical bond, O, S, N(R₉₁), B(R₉₁), P(R₉₁), or C(R₉₁)(R₉₂),
T₁ to T₄ may each independently be selected from a single bond, a double bond, *—N(R₉₃)—*′, *—B(R₉₃)—*′, *—P(R₉₃)—*′, *—C(R₉₃)(R₉₄)—*′, *—Si(R₉₃)(R₉₄)—*′, *—Ge(R₉₃)(R₉₄)—*′, *—S—*′, *—Se—*′, *—O—*′, *—C(═O)—*′, *—S(═O)—*′, *—S(═O)₂—*′, *—C(R₉₃)=*′, *=C(R₉₃)—*′, *—C(R₉₃)=C(R₉₄)—*′, *—C(═S)—*′, and *—C═C—*′,
wherein a substituent of the substituted C₅-C₃₀ carbocyclic group, a substituent of the substituted C₁-C₃₀ heterocyclic group, and R₉₁ to R₉₄ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted heterocycloalkyl group, a substituted or unsubstituted cycloalkenyl group, a substituted or unsubstituted heterocycloalkenyl group, a substituted or unsubstituted aryl group, a substituted or unsubstituted aryloxy group, a substituted or unsubstituted arylthio group, a substituted or unsubstituted heteroaryl group, a substituted or unsubstituted monovalent aromatic condensed polycyclic group, a substituted or unsubstituted monovalent aromatic condensed heteropolycyclic group, a substituted or unsubstituted monovalent non-aromatic condensed polycyclic group, a substituted or unsubstituted monovalent non-aromatic condensed heteropolycyclic group, —Si(Q₁)(Q₂)(Q₃), —Ge(Q₁)(Q₂)(Q₃), —C(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), and —P(═S)(Q₁)(Q₂),
*₁, *₂, *₃, and *₄ each indicate a binding site to M₁₁, and
Q₁, Q₂, and Q₃ may each independently be hydrogen, deuterium, —F, —Cl, —Br, —I, a hydroxyl group, a cyano group, a nitro group, an amidino group, a hydrazino group, a hydrazono group, an alkyl group, an alkenyl group, an alkynyl group, an alkoxy group, a cycloalkyl group, a heterocycloalkyl group, a cycloalkenyl group, a heterocycloalkenyl group, an aryl group, an alkylaryl group, an aryloxy group, an arylthio group, a heteroaryl group, an alkylheteroaryl group, a heteroaryloxy group, a heteroarylthio group, a monovalent aromatic condensed polycyclic group, a monovalent aromatic condensed heteropolycyclic group, a monovalent non-aromatic condensed polycyclic group, a monovalent non-aromatic condensed heteropolycyclic group, alkyl group substituted with at least one selected from deuterium, —F, a cyano group, an alkyl group, and an aryl group, and an aryl group substituted with at least one selected from deuterium, —F, a cyano group, an alkyl group, and an aryl group.

For example, in Formula 101, M₁₁ may be Ir or Pt, and particularly, Pt.

In an embodiment, the phosphorescent material (e.g., a phosphorescent compound) may include, for example, the following compounds:

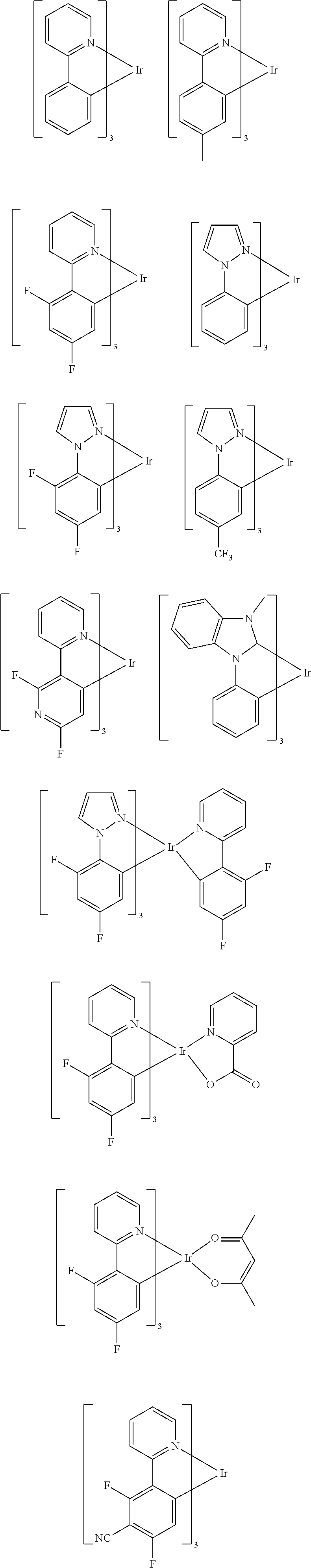

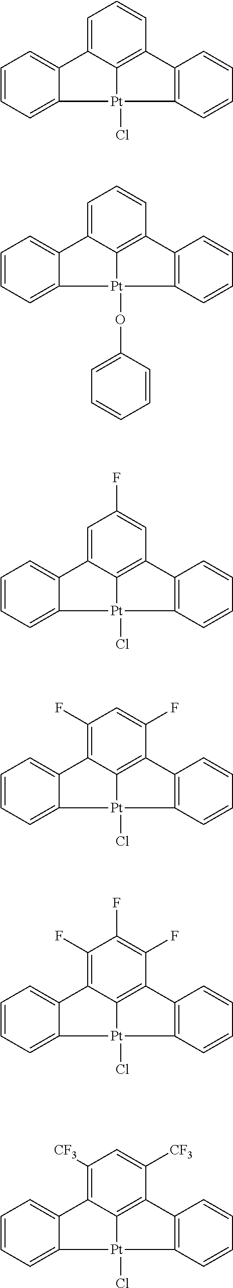

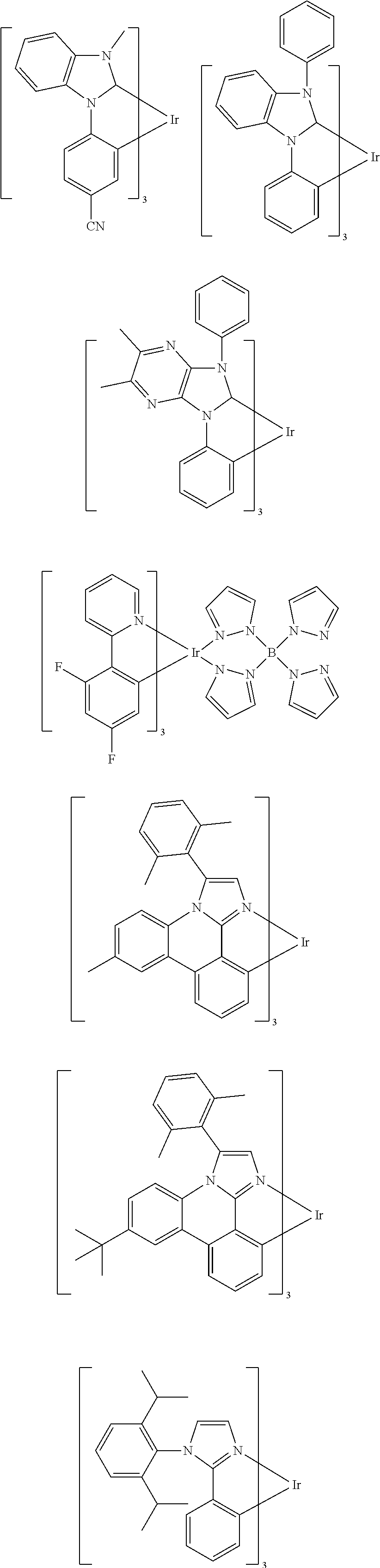

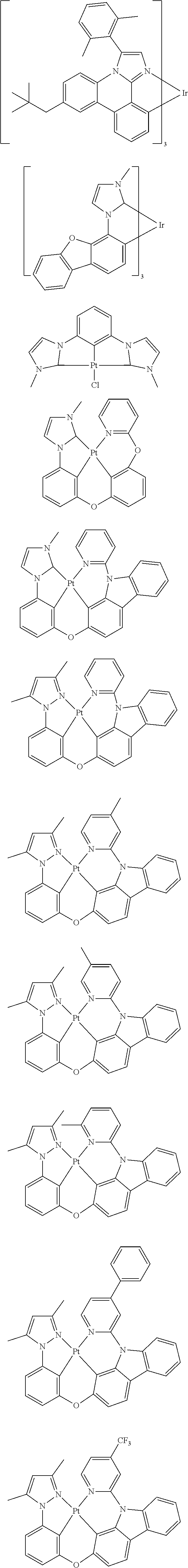

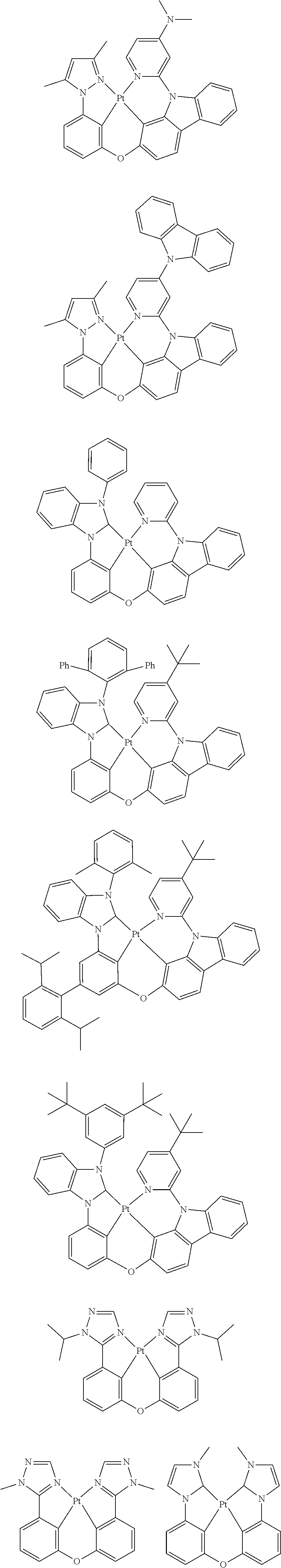

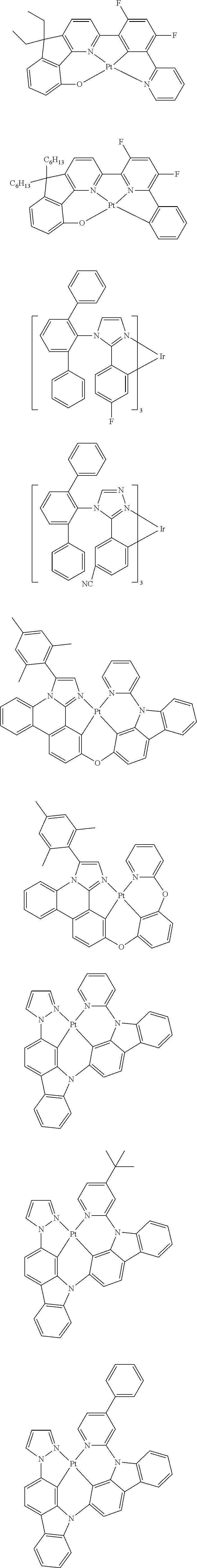

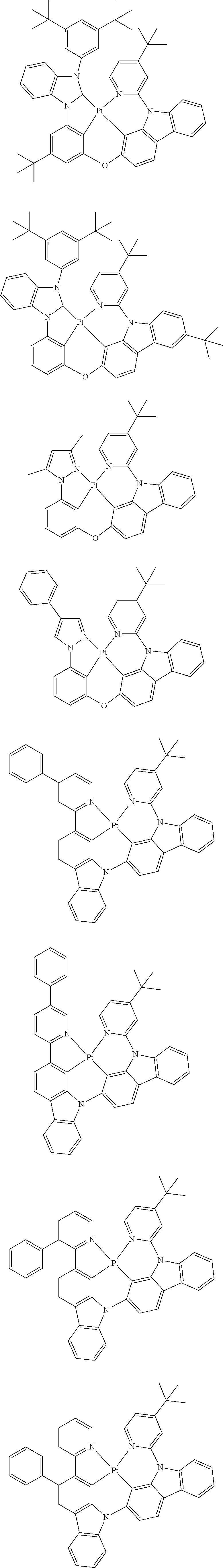

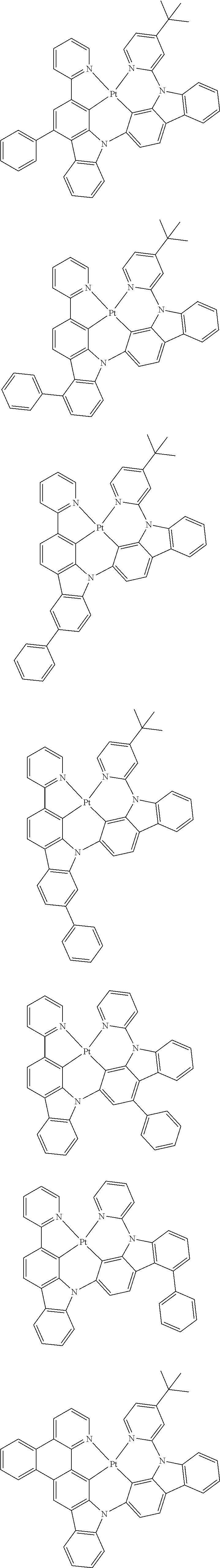

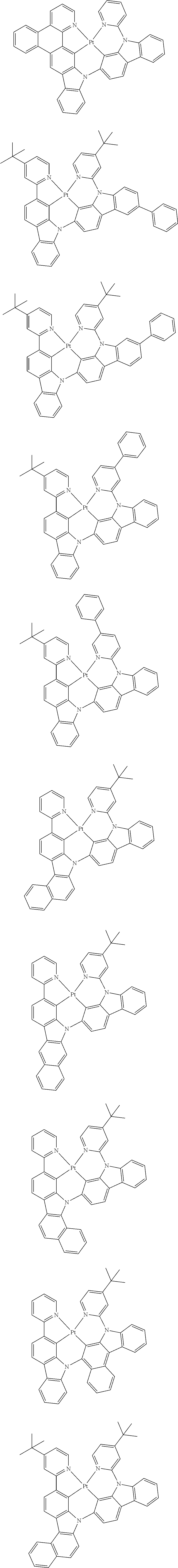

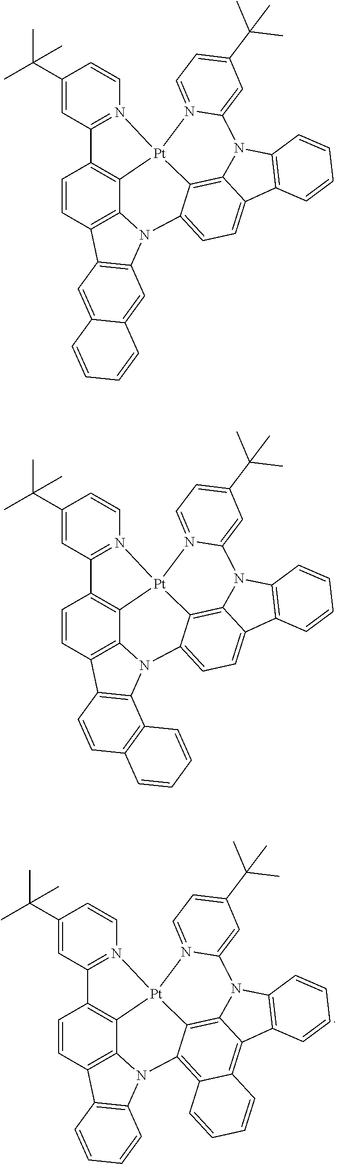

A person of ordinary skill understands that the composition can include one phosphorescent material, or two or more different phosphorescent materials. For example, the composition (or the emission layer) can include one or two or more of the phosphorescent compounds structurally defined above.

### Other Device Materials

For use as the material for an organic electroluminescent device of the disclosure, other materials used in an organic electroluminescent device may be used in addition to the compound represented by Formula 1 and the phosphorescent material.

The other materials used in an organic electroluminescent device are not particularly limited, and may be materials known in the art. For example, the other materials used in an organic electroluminescent device may include materials described as materials for use in the organic layer of the organic electroluminescent device. The materials may include at least one of a dopant material and a host material mentioned in the subsequent description of an emission layer of an organic electroluminescent device. Furthermore, the materials may include at least one material selected from the group consisting of a thermally activated delayed fluorescence material (TADF material or TADF compound) and a host material, as mentioned in the subsequent description of an emission layer of an organic electroluminescent device. Furthermore, a host material or both a TADF material and a host material may be used. In addition, both a TADF material and a host material may be used. In addition, a host material may be used.

In an embodiment of the disclosure, the organic electroluminescent device, e.g., an emission layer, may include the compound represented by Formula 1, the phosphorescent material, and a host material.

In an embodiment of the disclosure, the organic electroluminescent device the emission layer may consist of the compound represented by Formula 1, the phosphorescent material, and a host material.

In an embodiment of the disclosure, the composition as described herein may be a liquid material further containing a solvent. The solvent is not particularly limited, but may be a solvent with a boiling point of 100° C. to 350° C. under atmospheric pressure (101.3 kPa, 1 atm). The boiling point pf the solvent under atmospheric pressure may be in a range of about 150° C. to about 320° C. or about 180° C. to about 300° C. If the boiling point of the solvent under atmospheric pressure is within the ranges above, the film-forming properties or processability by a wet film formation method, such as an inkjet method, may be improved.

The solvent with the boiling point of 100° C. to 350° C. under atmospheric pressure is not particularly limited, and may utilize any known solvent. Hereinafter, examples of the solvent with the boiling point of 100° C. to 350° C. under atmospheric pressure are specified, but the disclosure is not limited thereto.

Examples of a hydrocarbon-based solvent include octane, nonane, decane, undecane, dodecane, and the like. Examples of an aromatic hydrocarbon-based solvent include toluene, xylene, ethylbenzene, n-propylbenzene, iso-propylbenzene, mesitylene, n-butylbenzene, sec-butylbenzene, 1-phenylpentane, 2-phenylpentane, 3-phenylpentane, phenylcyclopentane, phenylcyclohexane, 2-ethylbiphenyl, 3-ethylbiphenyl, and the like. Examples of an ether-based solvent include 1,4-dioxane, 1,2-diethoxyethane, diethyleneglycoldimethylether, diethyleneglycoldiethylether, anisole, ethoxybenzene, 3-methylanisole, m-dimethoxybenzene, and the like. Examples of a ketone-based solvent include 2-hexanone, 3-hexanone, cyclohexanone, 2-heptanone, 3-heptanone, 4-heptanone, cycloheptanone, and the like. Examples of an ester-based solvent include butylacetate, butylpropionate, butylbutyrate (heptylbutyrate), propylenecarbonate, methylbenzoate, ethylbenzoate, 1-propylbenzoate, 1-butylbenzoate, and the like. Examples of a nitrile-based solvent include benzonitrile, 3-methylbenzonitrile, and the like. Examples of an amide-based solvent include dimethylformamide, dimethylacetamide, N-methylpyrrolidone, and the like. These solvents may be used either individually or in combination with two or more types.

According to an embodiment, the composition for an organic electroluminescent device may not substantially containing a solvent,

Here, “not substantially containing a solvent” indicates that a solvent content in the material is less than 1 mass % with respect to the total mass of the composition. When the material for an organic electroluminescent device is not a liquid composition, the material may preferably contain substantially no solvent and may not contain none at all (0 mass % with respect to the total mass of the composition).

An amount of the compound represented by Formula 1 with respect to the total mass (e.g., the total mass excluding a solvent in the case of a liquid composition) of the composition for an organic electroluminescent device (particularly, a composition for an emission layer) may be the same as the amount of the compound represented by Formula 1 with respect to the total mass of an emission layer present in an organic electroluminescent device that will be described later.

In the material for an organic electroluminescent device (particularly, a material for an emission layer), an amount (parts by mass) of the phosphorescent material with respect to 100 parts by mass of the boron-based compound represented by Formula 1 may be the same as the amount of the phosphorescent material with respect to 100 parts by mass of the boron-based compound represented by Formula 1 in an emission layer which is the one in an organic electroluminescent device that will be described later.

An amount of the phosphorescent material with respect to the total mass (e.g., the total mass excluding a solvent in the case of a liquid composition) of the composition for an organic electroluminescent device (particularly, a composition for an emission layer) may be the same as the amount of the phosphorescent material with respect to the total mass of an emission layer present in an organic electroluminescent device that will be described later.

An amount of the TADF material with respect to the total mass (e.g., the total mass excluding a solvent in the case of a liquid composition) of the composition for an organic electroluminescent device (particularly, a composition for an emission layer) may be the same as the amount of the TADF material with respect to the total mass of an emission layer present in an organic electroluminescent device that will be described later.

In an organic electroluminescent device (particularly, a material for an emission layer), an amount (parts by mass) of the TADF material with respect to 100 parts by mass of the boron-based compound represented by Formula 1 may be the same as the amount of the TADF material with respect to 100 parts by mass of the boron-based compound represented by Formula 1 in an emission layer which is the one in an organic electroluminescent device that will be described later.

### Organic Electroluminescent Device

Another aspect of the disclosure provides an organic electroluminescent device including an organic layer including the composition for an organic electroluminescent device that may exhibit high luminescence efficiency and/or improved lifespan.

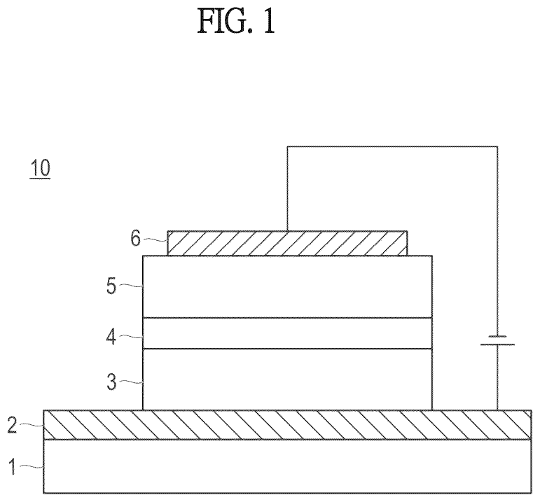

Hereinafter, referring to the figures, the organic electroluminescent device according to an aspect will be described in detail. FIGS. 1 to 3 are each a schematic cross-sectional view of an organic electroluminescent device according to an aspect.

FIGS. 1 to 3 are each a schematic cross-sectional view of an organic electroluminescent device according to an embodiment. However, the structure of the organic electroluminescent device of the disclosure is not limited to embodiments shown in FIGS. 1 to 3.

FIG. 1 is a schematic cross-sectional view of an organic electroluminescent device according to an embodiment. An organic electroluminescent device 10 includes a substrate 1, a first electrode 2, a hole transport region 3, an emission layer 4, an electron transport region 5, and a second electrode 6 that are sequentially stacked.

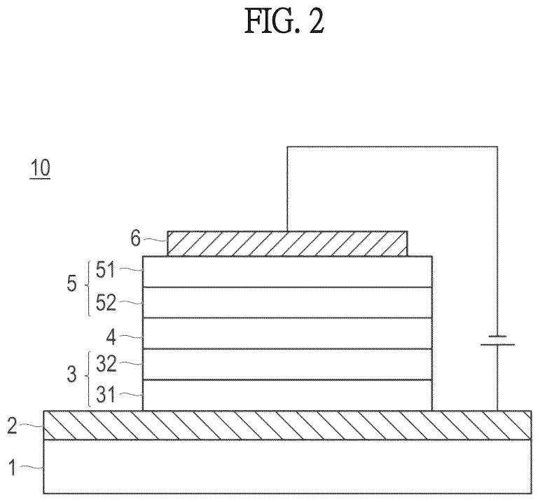

FIG. 2 is a schematic cross-sectional view of the organic electroluminescent device according to another embodiment. An organic electroluminescent device 10 according to another embodiment includes a substrate 1, a first electrode 2, a hole transport region 3, an emission layer 4, an electron transport region 5, and a second electrode 6 that are sequentially stacked. In FIG. 2, the hole transport region 3 includes a hole injection layer 31 and a hole transport layer 32 that are sequentially stacked. In addition, as shown in FIG. 2, the electron transport region 5 includes an electron transport layer 52 and an electron injection layer 51 that are sequentially stacked.

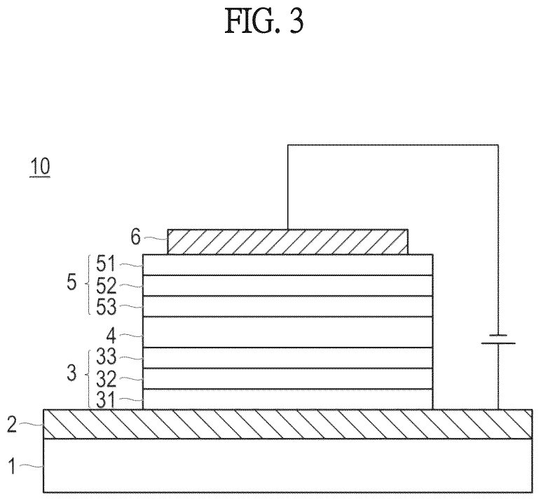

FIG. 3 is a schematic cross-sectional view of the organic electroluminescent device according to other embodiments. An organic electroluminescent device 10 according to other embodiments includes a substrate 1, a first electrode 2, a hole transport region 3, an emission layer 4, an electron transport region 5, and a second electrode 6 that are sequentially stacked. In FIG. 3, the hole transport region 3 includes a hole injection layer 31, a hole transport layer 32, and an electron-blocking layer 33 that are sequentially stacked. In addition, as shown in FIG. 3, the electron transport region 5 includes a hole-blocking layer 53, an electron transport layer 52, and an electron injection layer 51 that are sequentially stacked.

The composition for an organic electroluminescent device of the disclosure may be, for example, included in any one organic layer arranged between the first electrode 2 and the second electrode 6. The organic layer may refer to the hole injection layer 31, the hole transport layer 32, the emission layer 4, the electron transport layer 52, the electron injection layer 51, and the like. The composition for an organic electroluminescent device of the disclosure may be included in the emission layer 4.

In an embodiment, for example, the organic electroluminescent device may include a single emission layer or a plurality of emission layers. Here, the second electrode may be arranged on the first electrode.

In the present specification, when an element such as a layer, film, area, sheet, etc. is referred to as being “on top of” or “on” another element, it will be understood that the element may be “directly on” the another part element or intervening elements may be present therebetween. On the other hand, when an element such as a layer, film, area, sheet, etc. is referred to as being “below” or “under” another element, it will be understood that the element may be “directly below” the another part or intervening elements may be present therebetween. In addition, in the present specification, arrangement “on” something includes arrangement on the upper side as well as on the lower side or lower surface.

As described above, the composition for an organic electroluminescent device of the disclosure may be included in the emission layer. In other words, the organic layer may refer to the emission layer. Hereinafter, an embodiment in which the composition for an organic electroluminescent device of the disclosure is included in the emission layer will be described.

### Emission Layer

The emission layer may be a single layer of a single material, or may be a single layer including a plurality of different materials. In addition, the emission layer have a multiple-layer structure including a plurality of layers with each layer including one material or two or more different materials.

An amount of the compound represented by Formula 1 with respect to the total mass of the emission layer is not particularly limited, but may be 0.05 mass % or more. In addition, the amount of the compound represented by Formula 1 may be 0.1 mass % or more, 0.5 mass % or more, 1 mass % or more, 3 mass % or more, or 5 mass % or more. In addition, the amount of the compound represented by Formula 1 with respect to the total mass of the emission layer may be 50 mass % or less. In addition, the amount of the compound represented by Formula 1 may be 30 mass % or less, 25 mass % or less, 20 mass % or less, or 15 mass % or less. When the amount is within these ranges, the organic electroluminescent device may exhibit higher luminescence efficiency and/or longer lifespan.

The composition for the emission layer is not particularly included, but may include, for example, a host material and a dopant material. The compound represented by Formula 1 may be used as either the host material or the dopant material, for example, the compound represented by Formula 1 may be used as the dopant material. Particularly, the host does not emit light, and the compound represented by Formula 1 may emit light.

The composition for the emission layer is not particularly included, but may further include, for example, a known material for the emission layer. For example, the emission layer may include, in addition to the compound represented by Formula 1 and the phosphorescent material, an anthracene derivative, a pyrene derivative, a fluoranthene derivative, a chrysene derivative, a dihydrobenzoanthracene derivative, or a triphenylene derivative.

In addition, the emission layer may include, in addition to the compound represented by Formula 1 and the phosphorescent material, a known TADF material (TADF compound). TADF refers to the phenomenon where, in compounds with a small energy difference (AEst) between the singlet state and the triplet state, reverse intersystem crossing occurs between the triplet exciton and the singlet exciton. The TADF material refers to a material in which this phenomenon occurs.

The TADF material may include, for example, the following compounds:

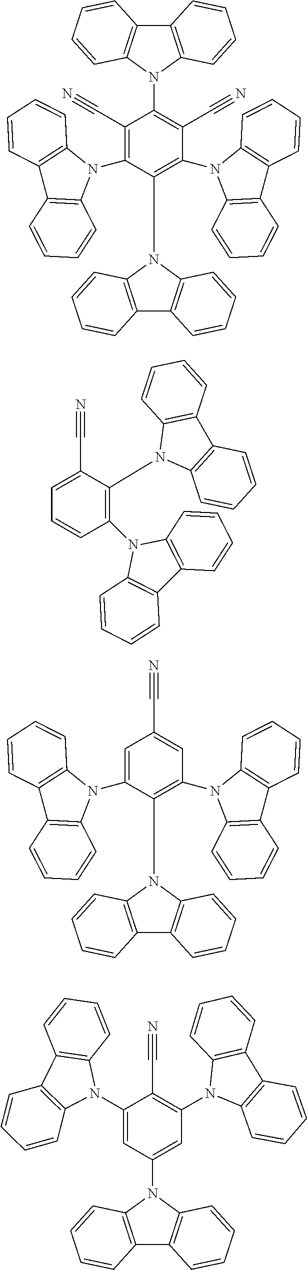

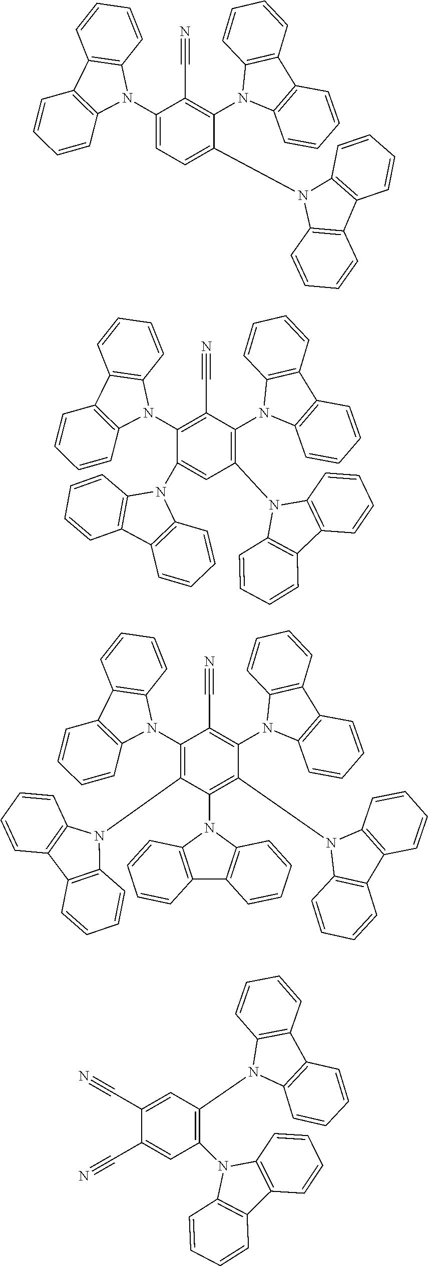

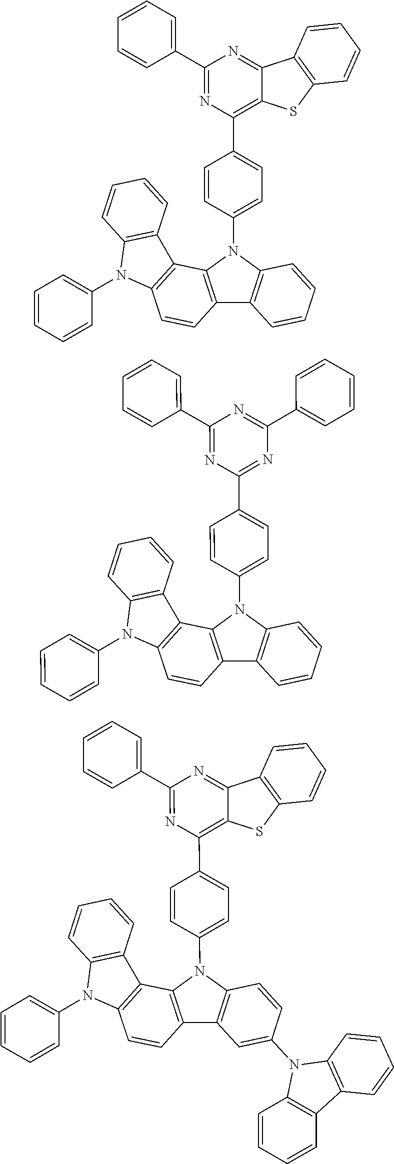

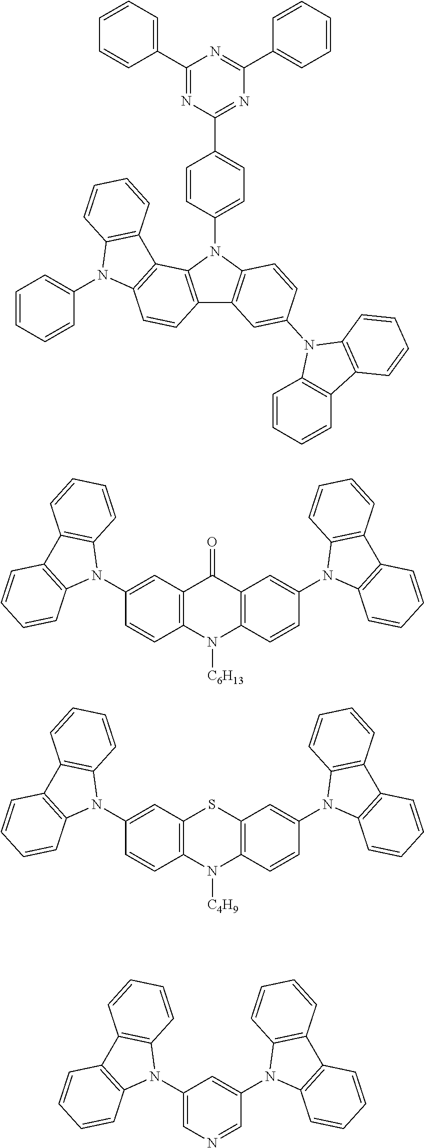

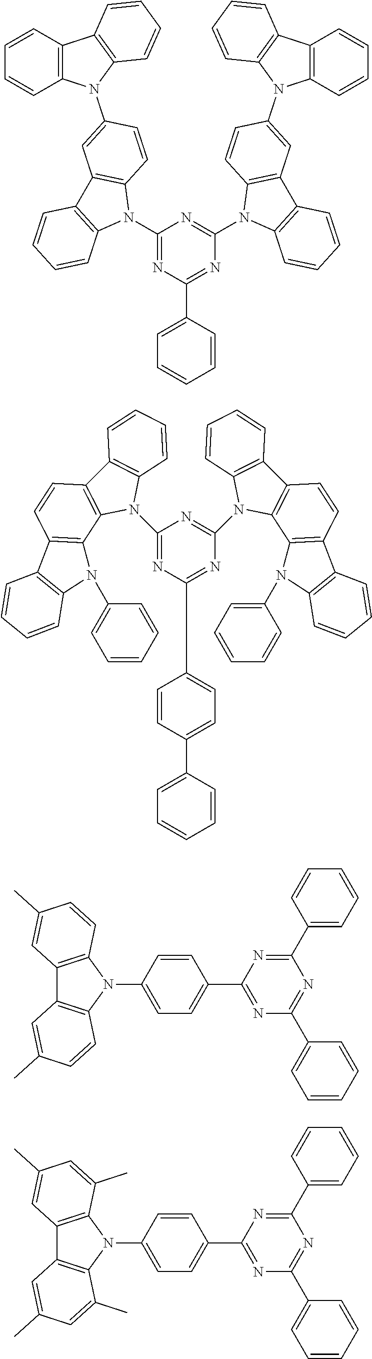

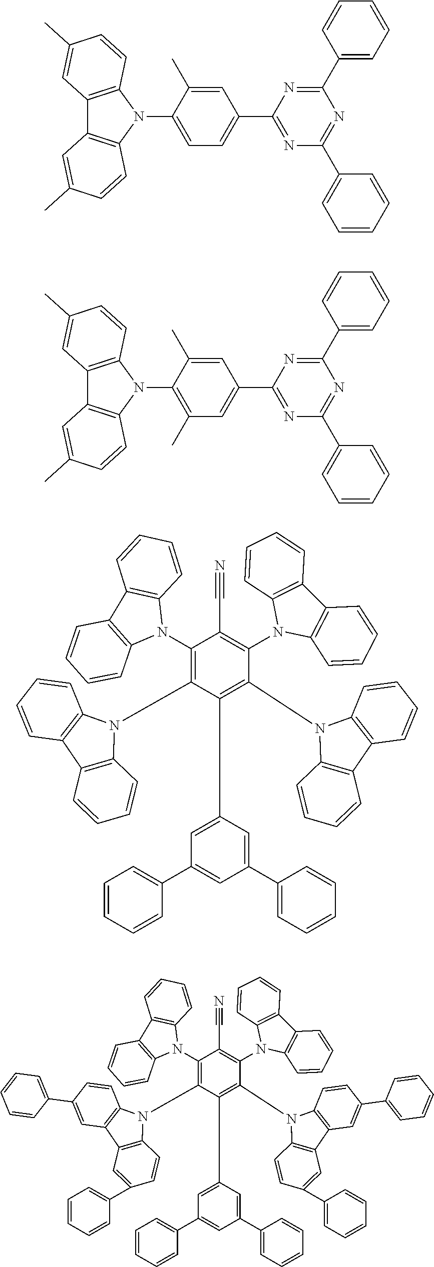

One or more TADF material may be used or present in the composition (emission layer).

When the emission layer includes the compound represented by Formula 1 and the phosphorescent material, the organic electroluminescent device may have improved luminescence efficiency and/or longer device lifespan. The reasons for this improvement are speculated as follows.

When holes and electrons recombine in the emission layer of the organic electroluminescent device, singlet excitons and triplet excitons are generated at a ratio of 1:3. Furthermore, in a device using only a fluorescent material as a luminescent material, only singlet excitons participate in luminescence, whereas in a device including a phosphorescent material as a luminescent material, both singlet excitons and triplet excitons may be used for luminescence. Consequently, the luminescence efficiency may be significantly improved in a device including a phosphorescent material as excitons generated or associated with the phosphorescent material may typically have a long lifespan of 1 μs or more. Because excitons are relatively unstable states with high energy an extended lifetime of an exciton may cause unwanted deterioration of material components in the emission layer, and lead to a reduction in device lifespan. When the phosphorescent material is present in addition to the compound represented by Formula 1 within the emission layer, the phosphorescent material may generate excitons with high efficiency. Furthermore, energy may be transferred from the generated excitons to the compound represented by Formula 1 via Förster energy transfer. Consequently, the compound represented by Formula 1 may exhibit highly efficient fluorescence. Moreover, the time duration of the exciton generated in (or associated with) the phosphorescent material may be shortened. Accordingly, the potential for material deterioration may be significantly reduced, and the device lifespan may be significantly improved.

An amount of the phosphorescent material with respect to the total mass of the emission layer is not particularly limited, but may be 0.1 mass % or more. In addition, the amount may be 0.5 mass % or more, 1 mass % or more, 3 mass % or more, or 5 mass % or moreIn addition, the amount of the phosphorescent material with respect to the total mass of the emission layer may be 50 mass % or less. In addition, the amount may be 40 mass % or less, 30 mass % or less, 25 mass % or less, or 20 mass % or less. When the amount is within these ranges, the organic electroluminescent device may exhibit improvement in color purity of luminescence, luminescence efficiency, and/or longer lifespan.

An amount of the TADF material with respect to the total mass of the emission layer is not particularly limited, but may be 0.1 mass % or more, 0.5 mass % or more, or 1 mass % or more. For example, the amount of the TADF material may be more preferably 3 mass % or more, and may be 5 mass % or more. In addition, the amount of the TADF material with respect to the total mass of the emission layer may be 50 mass % or less, 40 mass % or less, 30 mass % or less, 25 mass % or less, or 20 mass % or less. In addition, when the emission layer includes both the TADF material and the phosphorescent material, the total amount thereof may be within the ranges above. When the total amount is within these ranges, the organic electroluminescent device may exhibit improvement in color purity of luminescence, luminescence efficiency, and/or longer lifespan.

The amount of the phosphorescent material is not particularly limited, but may be 100 parts by mass or more with respect to 100 parts by mass of the compound represented by Formula 1. For example, the amount of the phosphorescent material may be, with respect to 100 parts by mass of the compound represented by Formula 1, 150 parts by mass or more, be 200 parts by mass or more, 400 parts by mass or more, or 600 parts by mass or more. In addition, the amount of the phosphorescent material may be 10000 parts by mass or less with respect to 100 parts by mass of the compound represented by Formula 1. For example, the amount of the phosphorescent material may be, with respect to 100 parts by mass of the compound represented by Formula 1, 7500 parts by mass or less, 5000 parts by mass or less, 3500 parts by mass or less, or 2000 parts by mass or less. When the amount is within these ranges, the organic electroluminescent device having superior color purity of luminescence, superior luminescence efficiency, and longer lifespan may be obtained.

When the emission layer includes the TADF material, an amount of the TADF material is not particularly limited, but may be 100 parts by mass or more with respect to 100 parts by mass of the compound represented by Formula 1. For example, the amount of the TADF material may be, with respect to 100 parts by mass of the compound represented by Formula 1, 150 parts by mass or more, 200 parts by mass or more, 350 parts by mass or more, or 500 parts by mass or more. In addition, the amount of the TADF material may be 10000 parts by mass or less with respect to 100 parts by mass of the compound represented by Formula 1. For example, the amount of the TADF material may be, with respect to 100 parts by mass of the compound represented by Formula 1, 7500 parts by mass or less, 5000 parts by mass or less, 3500 parts by mass or less, or 2500 parts by mass or less. In addition, when the emission layer includes both the TADF material and the phosphorescent material, the total amount thereof may be within the ranges above. When the amount is within these ranges, the organic electroluminescent device may exhibit improvement in color purity of luminescence, luminescence efficiency, and/or longer lifespan may.

The composition for the emission layer is not particularly included, but may include, for example, a known host material. For example, the emission layer may include at least one of bis[2-(diphenylphosphino)phenyl]etheroxide (DPEPO), 4,4′-bis(carbazole-9-yl) biphenyl (CBP), 3,3′-bis(carbazole-9-yl) biphenyl(mCBP), 1,3-bis(carbazole-9-yl)benzene (mCP), 2,8-bis(diphenylphosphoryl)dibenzo[b,d]furan (PPF), 4,4′,4″-tri (carbazole-9-yl)triphenylamine (TcTa), and 1,3,5-tris(N-phenylbenzimidazole-2-yl)benzene (TPBi). However, without being limited thereto, the emission layer may include, for example, tris(8-hydroxyquinolino)aluminum (Alq₃), CBP, poly(n-vinylcarbazole) (PVK), 9,10-di(naphthalene-2-yl) anthracene (ADN), 4,4′,4″-tris(carbazole-9-yl)-triphenylamine (TCTA), 1,3,5-tris(N-phenylbenzimidazole-2-yl)benzene (TPBi), 3-tert-butyl-9,10-di(naphtho-2-yl) anthracene (TBADN), distyrylarylene (DSA), 4,4′-bis(9-carbazolryl)-2,2′-dimethyl-biphenyl (CDBP), 2-methyl-9,10-bis(naphthalene-2-yl) anthracene (MADN), DPEPO, hexaphenylcyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), or PPF.

In addition, the emission layer may include, as the host material, a material having a highest occupied molecular orbital (HOMO) level of −5.2 eV or less. In addition, the emission layer may include, as the host material, a material having a lowest unoccupied molecular orbital (LUMO) level of −1.4 eV or less. The reason for using a host material having low HOMO and LUMO levels and high electron-transporting ability is that such a host material may offer advantages such as improved driving durability in an organic electroluminescent device, particularly an organic electroluminescent device emitting blue light.

The host material is not particularly limited, but in an embodiment, may be the compound represented by Formula A described in the article titled “An Alternative Host Material for Long-Lifespan Blue Organic Light-Emitting Diodes Using Thermally Activated Delayed Fluorescence” by Soo-Ghang IhN, Namheon Lee, Soon Ok Jeon, Myungsun Sim, Hosuk Kang, Yongsik Jung, Dal Ho Huh, Young Mok Son, Sae Youn Lee, Masaki Numata, Hiroshi Miyazaki, Rafael Gómez-Bombarelli, Jorge Aguilera-Iparraguirre, Timothy Hirzel, Alán Aspuru-Guzik, Sunghan Kim, and Sangyoon Lee, Advanced Science News 2017, 4, 1600502. When the emission layer is formed using a combination of the aforementioned host materials, blue luminescent materials known in the art may involve deep hole traps, causing undesirable effects such as increased driving voltage. Meanwhile, the compound represented by Formula 1 exhibits weak hole-trapping properties, and thus, is expected to suppress the occurrence of increased driving voltage.

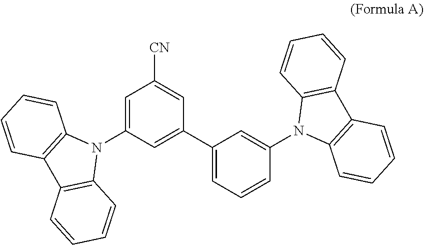 [SMILES: N#Cc1cc(-c2cccc(-n3c4ccccc4c4ccccc43)c2)cc(-n2c3ccccc3c3ccccc32)c1]

In addition, the emission layer may include, as the host material, the following compounds:

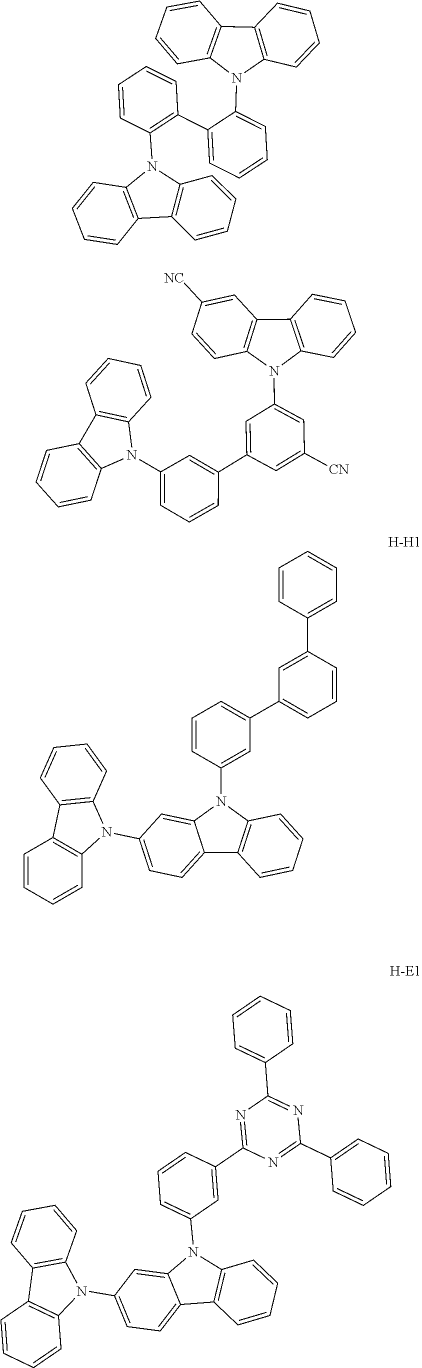

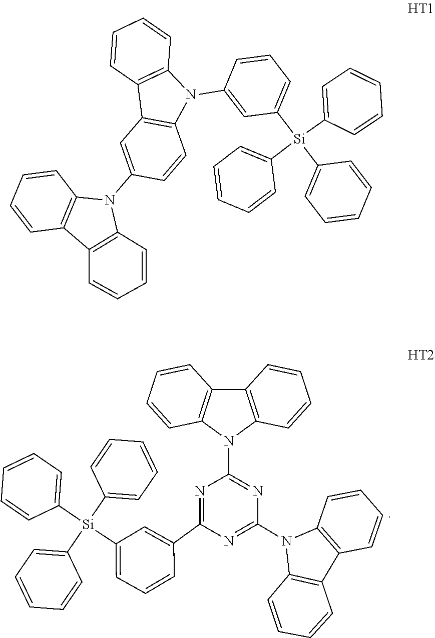 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

Among these compounds, the emission layer may include preferably, as the host material, at least one of Compound HT1 and Compound HT2, for example, both Compound HT1 and Compound HT2.

An amount of the host material with respect to the total mass of the emission layer is not particularly limited, but may be 5 mass % or more. In addition, the amount may be 10 mass % or more, 20 mass % or more, or 30 mas % or more. The amount of the host material with respect to the total mass of the emission layer may be 99 mass % or less, 95 mass % or less, or 90 mass % or less, 80 mass % or less, or 75 mass % or less. When the amount is within these ranges, the organic electroluminescent device may exhibit improvement in color purity of luminescence, luminescence efficiency, and/or longer lifespan.

When the emission layer includes the host material, the amount of the host material is not particularly limited, but may be 1000 parts by mass or more with respect to 100 parts by mass of the compound represented by Formula 1. For example, the amount of the host material may be, with respect to 100 parts by mass of the compound represented by Formula 1, 2000 parts by mass or more, 3000 parts by mass or more, 5000 parts by mass or more, or 7000 parts by mass or more,. In addition, the amount of the host material may be 200,000 parts by mass or less with respect to 100 parts by mass of the compound represented by Formula 1. In addition, the amount of the host material may be, with respect to 100 parts by mass of the compound represented by Formula 1, 150,000 parts by mass or less, 100,000 parts by mass or less, 90,000 parts by mass or less, or 75,000 parts by mass or less. When the amount is within these ranges, the organic electroluminescent device may exhibit improvement in color purity of luminescence, luminescence efficiency, and/or longer lifespan may.

The material for the emission layer is not particularly included, but may include, for example, a known dopant material. For example, the dopant material may include a styryl derivative (e.g., 1,4-bis[2-(3-N-ethylcarbazolyl) vinyl]benzene (BCzVB), 4-(di-p-tolylamino)-4′-[(di-p-tolylamino) styryl]stilbene (DPAVB), or N-(4-((E)-2-(6-((E)-4-(diphenylamino) styryl) naphthalene-2-yl) vinyl)phenyl)-N-phenylbenzeneamine (N-BDAVBi)), perylene or a derivative thereof (e.g., 2,5,8,11-tetra-tert-butylperylene (TBP)), or pyrene or a derivative thereof (e.g., 1,1-dipyrene, 1,4-dipyrenylbenzene, or 1,4-bis(N, N-diphenylamino)pyrene), and the like.

The emission layer may be a single layer of a single material, or may be a single layer including two or more different materials. In addition, the emission layer have a multiple-layer structure including two or more layers with each layer including one material or two or more different materials.

A thickness of the emission layer is not particularly limited, but may be in a range of about 1 nm to about 100 nm, e.g., in a range of about 10 nm to about 50 nm.

An emission wavelength of the emission layer (i.e., emission wavelength of the organic electroluminescent device including the emission layer) is not particularly limited. However, the organic electroluminescent device may emit light having a peak in a wavelength region of about 360 nm to about 515 nm, about 380 nm to about 505 nm, about 400 nm to about 500 nm, or about 420 nm to about 490 nm. In particular, the emission layer may emit light having a peak wavelength region of about 455 nm to about 475 nm. When the emission wavelength is within the ranges above, blue luminescence with relatively good color purity, may be obtained.

In addition, the organic electroluminescent device may have an FWHM of an emission spectrum of about 30 nm or less, about 25 nm or less, about 24 nm or less, or about 5 nm or more. When the FWHM is within the ranges above, the device may exhibit luminescence with higher color purity.

Hereinafter, each region and each layer other than the emission layer 4 will be described in detail.

The organic electroluminescent device 10 may include a substrate 1. The substrate 1 may be a substrate used in a general organic electroluminescent device. For example, the substrate 1 may be a glass substrate, a silicon substrate, or a transparent plastic substrate having excellent mechanical strength, thermal stability, transparency, surface smoothness, ease of handling, and water repellency, but embodiments are not limited thereto.

The first electrode 2 may be arranged on the substrate 1. The first electrode 2 may specifically be an anode, and to facilitate injection of holes, may be formed of a material with a high work function selected from a metal, an alloy, an electrically conductive compound, and a combination thereof. The first electrode 2 may be a pixel electrode. The first electrode 2 may be a reflective electrode, a transmissive electrode, or a transmissive electrode.

A material for forming the first electrode 2 is not particularly limited. However, when the first electrode 2 is a transparent electrode, the material may be, for example, indium tin oxide (ITO), indium zinc oxide (IZO), tin oxide (SnO₂), zinc oxide (ZnO), indium tin zinc oxide (ITZO), or the like, having excellent transparency and conductivity. When the first electrode 2 is a transflective electrode or a reflective electrode, the first electrode 2 may include Ag, Mg, Cu, Al, Pt, Pd, Au, Ni, Nd, Ir, Cr, Li, Ca, In, LiF/Ca, LiF/Al, Mo, Ti, or a compound or mixture thereof (e.g., a mixture of Ag and Mg or a mixture of Mg and In).

The first electrode 2 may be a single layer including a single material or a single layer including a plurality of different materials. In an embodiment, the first electrode 2 may have a multi-layer structure including a plurality of layers including various different materials.

A thickness of the first electrode 2 is not particularly limited, but may be in a range of about 10 nm to about 1000 nm or about 100 nm to about 300 nm.

The hole transport region 3 may be arranged on the first electrode 2. The hole transport region 3 may include at least one of the hole injection layer 31, the hole transport layer 32, the electron-blocking layer 33, and a hole buffer layer (not shown).

The hole transport region 3 may be a single layer including a single material or a single layer including a plurality of different materials. In an embodiment, the hole transport region 3 may have a multi-layer structure including a plurality of layers including various different materials.

The hole transport region 3 may include only the hole injection layer 31 or only the hole transport layer 32. In an embodiment, the hole transport region 3 may be a single layer including a hole-injecting material and a hole-transporting material. The hole transport region 3 may have a hole injection layer/hole transport layer structure, a hole injection layer/hole buffer layer structure, a hole injection layer/hole transport layer/hole buffer layer structure, or a hole injection layer/hole transport layer/electron blocking layer structure, wherein the constituent layers for each structure are stacked on the first electrode 2 in the stated order.

For example, the hole transport region 3 may have a hole injection layer 31/hole transport layer 32/hole buffer layer (not shown) structure. In addition, for example, the hole transport region 3 may have a hole injection layer 31/hole buffer layer (not shown) structure, wherein the constituent layers are stacked on the first electrode 2 in the stated order. For example, the hole transport region 3 may have a hole transport layer 32/hole buffer layer (not shown) structure, wherein the constituent layers are stacked on the first electrode 2 in the stated order. For example, the hole transport region 3 may have a hole injection layer 31/hole transport layer 32/electron-blocking layer 33 structure, wherein the constituent layers are stacked on the first electrode 2 in the stated order. However, the structures of the hole transport region 3 are not limited to the aforementioned embodiments.

The hole injection layer 31 and other layers constituting the hole transport region 3 are not particularly limited, but may include a known hole-injecting material and/or a hole-transporting material.

The hole-injecting material may be, for example, a phthalocyanine compound, such as copper phthalocyanine, N,N′-diphenyl-N, N′-bis-[4-(phenyl-m-tryl-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphorsulfonic acid (PANI/CSA), polyaniline/poly(4-styrenesulfonate) (PANI/PSS), N,N′-di(naphthalen-1-yl)-N,N′-diphenyl-benzidine (NPB), polyetherketone (TPAPEK) including triphenylamine, 4-isopropyl-4′-methyldiphenyliodonium tetrakis(pentafluorophenyl) borate, dipyrazino[2,3-f:2,3′-h]quinoxaline-2,3,6,7,10,11-hexacarbonitrile (HAT-CN), 1,3,4,5,7,8-hexafluorotetracyano-2,6-naphthoquinodimethane (F6-TCNNQ), and the like.

The hole-transporting material may be, for example, a carbazole-based derivative, such as N-phenylcarbazole, polyvinylcarbazole, etc., a fluorene-based derivative, a triphenylamine-based derivative, such as N,N′-bis(3-methylphenyl)-N,N′-diphenyl-[1,1-biphenyl]-4,4′-diamine (TPD), 4,4′,4″-tris(N-carbazolyl)triphenylamine (TCTA), etc., N,N′-do(naphthalen-1-yl)-N,N′-diphenyl-benzidine (NPB), 4,4′-cyclohexylidenbis[N,N-bis(4-methylphenyl)benzeneamine] (TAPC), 4,4′-bis[N,N′-(3-tryl)amino]-3,3′-dimethylbiphenyl (HMTPD), 1,3-bis(N-carbazolyl)benzene (mCP), Compound H1, Compound H2, Compound H3, and the like:

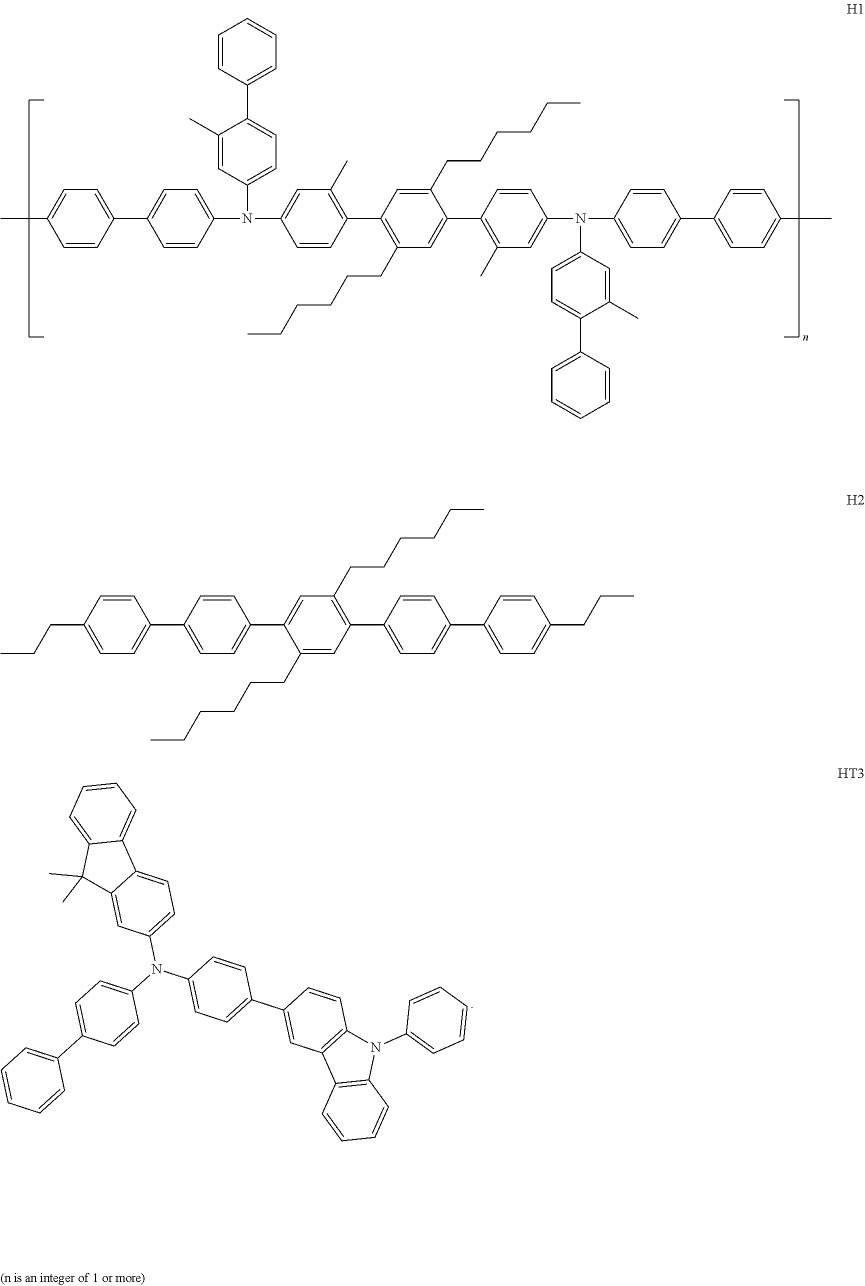

The hole transport region 3 may further include, in addition to the aforementioned materials, a charge-generating material to improve the conductive properties. The charge-generating material may be uniformly or non-uniformly dispersed in the hole transport region.

The charge-generating material is not particularly limited, but may be, for example, a p-dopant or the like. Examples of the p-dopant include a quinone derivative, such as tetracyanoquinodimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, but the p-dopant is not limited thereto.

The hole buffer layer (not shown) may increase luminescence efficiency by compensating for an optical resonance distance according to the wavelength of light emitted by the emission layer. A material for forming the hole buffer layer (not shown) is not particularly limited, and may include a known hole buffer layer material. For example, the material may include the compounds included in the hole transport region.

The electron blocking layer 33 may prevent injection of electrons from the electron transport region 5 to the hole transport region 3. A material included in the electron-blocking layer 33 is not particularly limited, and may include a known electron-blocking layer material. For example, the material may include the host material included in the emission layer, wherein the host material includes Compound H-H1, Compound HT1, and the like.

A thickness of the hole transport region 3 is not particularly limited, but may be in a range of about 1 nm to about 1000 nm, and specifically about 10 nm to about 500 nm. In addition, a thickness of the hole injection layer 31 is not particularly limited, but may be in a range of about 3 nm to about 100 nm. A thickness of the hole transport layer 32 is not particularly limited, but may be in a range of about 3 nm to about 200 nm, and specifically about 3 nm to about 150 nm. A thickness of the electron-blocking layer 33 is not particularly limited, but may be in a range of about 1 nm to about 100 nm. In addition, a thickness of the hole buffer layer (not shown) is not particularly limited as long as the thickness is within a range that allows the hole buffer layer to function without interfering with the function of the organic electroluminescent device. When the thicknesses of the hole transport region 3, the hole injection layer 31, the hole transport layer 32, or the electron-blocking layer 33 are within the ranges above, excellent hole transport characteristics may be obtained without a substantial increase in driving voltage.

The emission layer 4 may be arranged between the hole transport region 3 and the electron trans[port region 5. The emission layer 4 may be understood by referring to the preceding description.

The electron transport region 5 may be arranged on the emission layer 4. The electron transport region 5 may include at least one of a hole-blocking layer 53, an electron transport layer 52, and electron injection layer 51.

The electron transport region 5 may be a single layer including a single material or a single layer including a plurality of different materials. In an embodiment, the electron transport region 5 may have a multi-layer structure including a plurality of layers including various different materials.

The electron transport region 5 may include only the electron transport layer 52 or only the electron injection layer 51. In an embodiment, the electron transport region 5 may be a single layer including an electron-injecting material and an electron-transporting material. The electron transport region 5 may include an electron transport layer/electron injection layer structure or a hole blocking layer/electron transport layer/electron injection layer structure, wherein constituent layers for each structure are stacked on the emission layer 4 in the stated order.

The electron injection layer 51 is not particularly limited, may include, for example, a known electron-injecting material. The electron-injecting material may include, for example, a lanthanide metal, such as lithium quinolate (LiQ), Li₂O, BaO, and Yb, and a halogenated metal, such as LiF, NaCl, CsF, and RbCl, and the like.

In an embodiment, the electron injection layer 51 may include both an electron-transporting material which will be described below and an insulating organometallic salt. The organometallic salt is not particularly limited, but may include, for example, a material having an energy band gap or 4 eV or higher. The organometallic salt may include, for example, metal acetate, metal benzoate, a metal salt of acetic acid, metal acetylacetonate, or metal stearate.

The electron transport layer 52 is not particularly limited, but may include, for example, a known electron transport material. The electron-transporting material may include, for example, an anthracene-based compound, tris(8-hydroxyquinolinolate)aluminum (Alq₃), 1,3,5-tri[(3-pyridyl)-phen-3-yl]benzene, 2,4,6-tris(3′-pyridin-3-yl) biphenyl-3-yl)-1,3,5-triazine, 2-(4-(N-phenylbenzoimidazolyl-1-ylphenyl)-9,10-dinaphthylanthracene, 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), tBu-PBD (2-(4-biphenyl)-5-(4-tert-butylphenyl)-1,3,4-oxadiazole), bis(2-methyl-8-quinolinolate-N1,O8)-(1,1′-biphenyl-4-ollato)aluminum (BAlq), berylliumbis(benzoquinoline-10-olato (Bebq₂), 9,10-di(naphthalen-2-yl) anthracene (ADN), lithium quinolate (LiQ), Compound ET1, Compound H91, and the like:

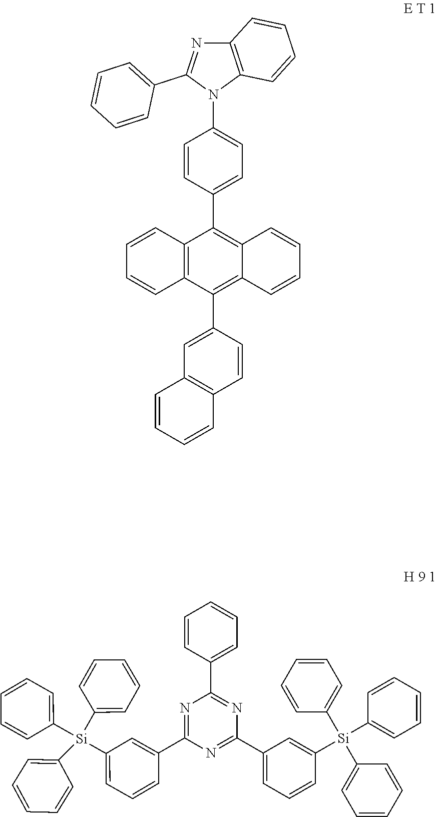 [SMILES: c1ccc(-c2nc3ccccc3n2-c2ccc(-c3c4ccccc4c(-c4ccc5ccccc5c4)c4ccccc34)cc2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

The hole-blocking layer 53 is a layer that prevents injection of holes from the hole transport region 3 to the electron transport region 5. A material included in the hole-blocking layer 53 is not particularly limited, and may include a known hole-blocking material. The hole-blocking layer 53 may include, for example, BCP, Bphen, and the like. In addition, the hole-blocking material may include, for example, the host material included in the emission layer, wherein the host material includes Compound H-E1, Compound HT2, and the like.

A thickness of the electron transport region 5 is not particularly limited, but may be in a range of about 0.1 nm to about 210 nm, about 30 nm to about 150 nm, or about 30 nm to about 80 nm. A thickness of the electron transport layer 52 is not particularly limited, but may be in a range of about 10 nm to about 100 nm, and more specifically about 15 nm to about 50 nm. A thickness of the hole-blocking layer 53 is not particularly limited, but may be in a range of about 5 nm to about 100 nm, and more specifically about 15 nm to about 50 nm. A thickness of the electron injection layer 51 is not particularly limited, but may be in a range of about 0.1 nm to about 10 nm, and more specifically about 0.3 nm to about 9 nm. When the thickness of the electron injection layer 51 is the ranges above, improved electron injection characteristics may be obtained without a substantial increase in driving voltage. When the thickness of the electron transport region 5, the electron injection layer 51, the electron transport layer 52, or the hole blocking layer 53 is within the ranges above, excellent electron transport characteristics may be obtained without a substantial increase in driving voltage.

The second electrode 6 is arranged on the electron transport region 5. The second electrode 6 may have conductivity. The second electrode 6 may specifically be a cathode, and to facilitate injection of electrons, may be formed of a material with a relatively low work function selected from a metal, an alloy, or a conductive compound. In the organic electroluminescent device according to an aspect, the second electrode 6 may be a common electrode. In addition, the second electrode 6 may be a transmissive electrode, a transmissive electrode, or a reflective electrode. The second electrode 6 may have a single-layer structure or a multi-layer structure including a plurality of layers.

A material for forming the second electrode 6 is not particularly limited, but may include, for example, a metal, a metal alloy, a conductive compound, and the like. When the second electrode 6 is a transmissive electrode, the second electrode 6 may include, for example, a transparent metal oxide, such as ITO, IZO, ZnO, ITZO, and the like. When the second electrode 6 is a transflective electrode or a reflective electrode, the second electrode 6 may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg).

The second electrode 6 may be a single layer including a single material or a single layer including a plurality of different materials. In an embodiment, the second electrode 6 may have a multi-layer structure including a plurality of layers including various different materials.

In addition, a thickness of the second electrode 6 is not particularly limited, but may be in a range of about 10 nm to about 1,000 nm.

The second electrode 6 may be further connected to an auxiliary electrode (not shown). When the second electrode 6 is connected to an auxiliary electrode, a resistance of the second electrode 6 may be further reduced.

A capping layer (not shown) may be further arranged on the second electrode 6. The capping layer (not shown) is not particularly limited, but may include, for example, α-NPD, NPB, TPD, m-MTDATA, Alq3, CuPc, TPD15(N4,N4,N4′,N4′-tetra(phenyl-4-yl) biphenyl-4,4′-diamine), TCTA, N,N′-bis(naphthalene-1-yl), and the like.

In addition, each layer of the organic electroluminescent device 10 may be formed single-layered or multi-layered.

Methods of preparing each layer of the organic electroluminescent device 10 according to an embodiment are not particularly limited, and in general, the preparation methods are well known to a person or ordinary skill in the art. For example, each layer may be prepared by various methods such as a vacuum deposition method, a solution coating method, a laser printing method, a Langmuir-Blodgett (LB) method, a laser-induced thermal imaging (LITI) method, and the like.

The solution coating may include spin coating, casting, micro-gravure coating, gravure coating, bar coating, roll coating, wire bar coating, dip coating, spray coating, screen printing, flexographic printing, offset printing, or ink-jet printing.

The vacuum deposition may be performed at a deposition temperature in a range of about 100° C. to about 500° C., at a vacuum degree in a range of about 10⁻⁸ torr to about 10⁻³ torr, and at a deposition rate in a range of about 0.01 nm per second (nm/sec) to about 10 nm/sec, though the conditions may vary depending on a compound that is used and a structure and thermal properties of a desired layer.

In an embodiment, the first electrode 2 may be an anode, and the second electrode 6 may be a cathode.

In another embodiment, the first electrode 2 may be a cathode, and the second electrode 6 may be an anode.

In the organic electroluminescent device 10 of FIGS. 1 to 3, when a voltage is applied to each of the first electrode 2 and the second electrode 6, holes injected from the first electrode 2 may move toward the emission layer 4 through the hole transport region 3, and electrons injected from the second electrode 6 may move toward the emission layer 4 through the electron transport region 5. The holes and the electrons may recombine in the emission layer 4 to produce excitons, and these excitons may transition from an excited state to a ground state to thereby generate light.

In the organic electroluminescent device 10 of FIGS. 1 to 3, the emission layer 4 may preferably include the composition for an organic electroluminescent device, but the organic layer other than the emission layer 4 may include the composition for an organic electroluminescent device. In addition, the emission layer 4 and the organic layer other than the emission layer 4 may include the composition for an organic electroluminescent device.

The organic electroluminescent device may be included in various types of electronic apparatuses.

The electronic apparatus may further include a thin-film transistor in addition to the aforementioned organic electroluminescent device. The thin-film transistor may include a source electrode, a drain electrode, and an active layer, wherein any one of the source electrode and the drain electrode may be electrically connected to any one of the first electrode and the second electrode of the organic electroluminescent device.

Hereinafter, a compound and an organic light-emitting device according to embodiments are described in detail with reference to Synthesis Example and Examples. However, the organic electroluminescent device is not limited thereto.

### EXAMPLES

### Synthesis Example 1: Synthesis of Compound 1

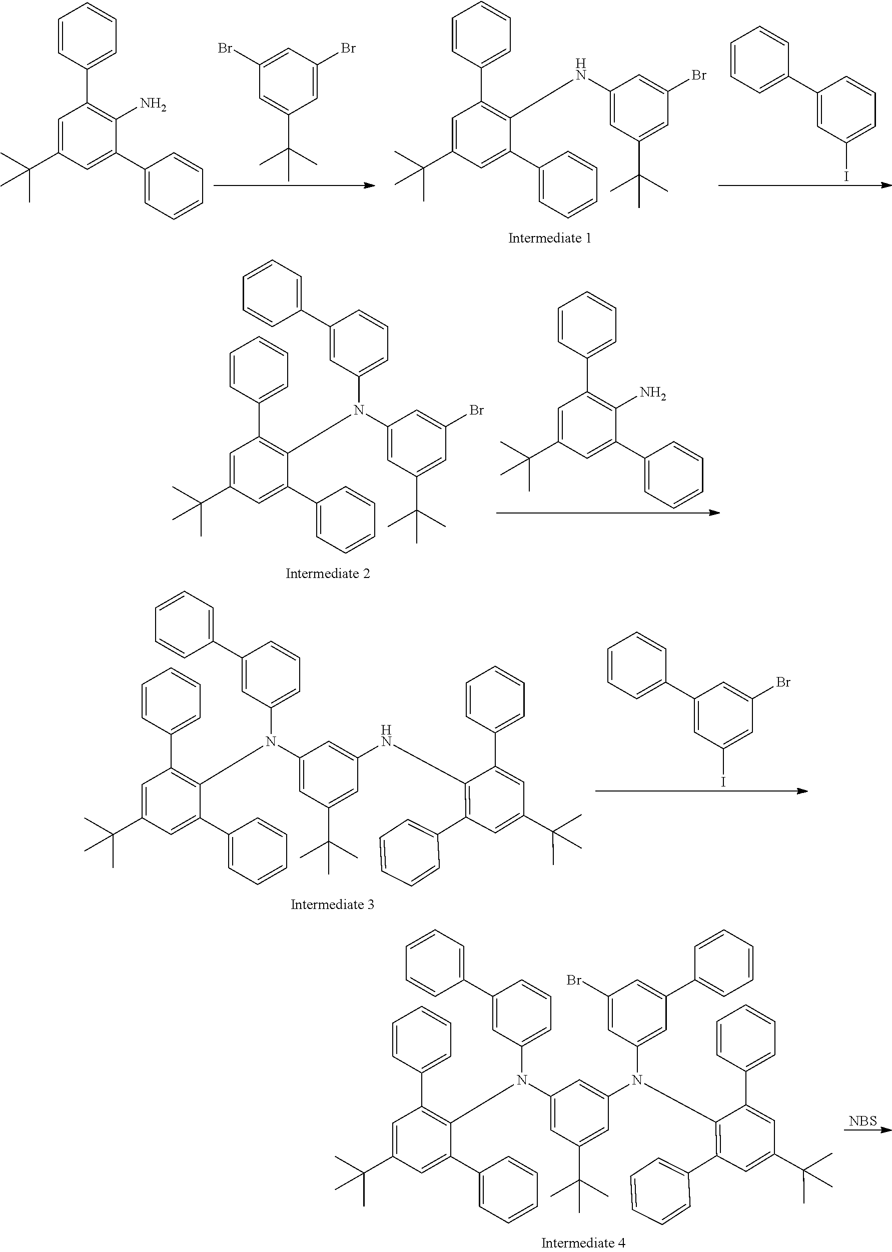

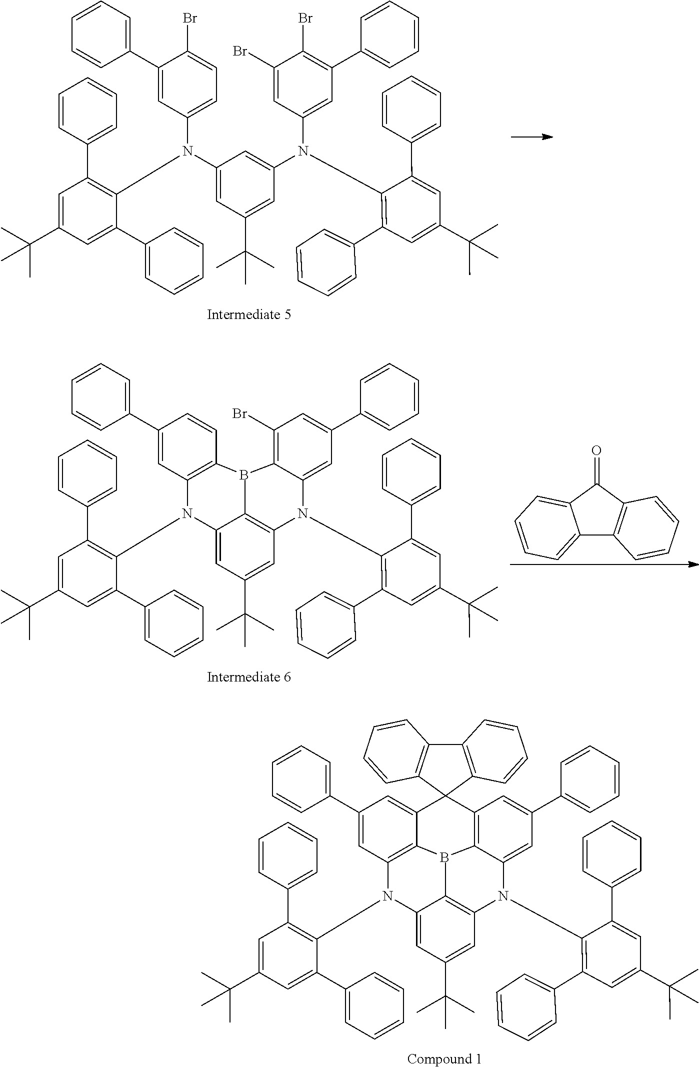

### Synthesis of Intermediate 1

In a reaction vessel, 10.0 g (33.2 mmol, 1.0 equiv.) of 5′-(tert-butyl) [1,1′:3′-1″-terphenyl]-2′-amine, 9.69 g (33.2 mmol, 1.0 equiv.) of 1,3-dibromo-5-tert-butylbenzene, 4.78 g (49.8 mmol, 1.5 equiv.) of sodium tert-butoxide, 0.46 g (0.50 mmol, 0.015 equiv.) of tris(dibenzylideneacetone) dipalladium (0), 0.83 g (1.33 mmol, 0.040 equiv.) of 2,2′-bis(diphenylphosphino)-1,1′-binaphthyl (BINAP), and 160 mL of toluene were added, and the mixed solution was stirred at 75° C. for 16 hours under a nitrogen atmosphere. Thereafter, the mixture was diluted with toluene and filtered through celite, and then, silica gel. The filtrate was concentrated and dispersed in methanol for washing to obtain Intermediate 1 (amount of 12.0 g, yield of 70%).

### Synthesis of Intermediate 2

In a reaction vessel, 12.0 g (23.4 mmol, 1.0 equiv.) of Intermediate 1, 7.87 g (28.1 mmol, 1.2 equiv.) of 3-iodobiphenyl, 9.71 g (70.2 mmol, 3.0 equiv.) of potassium carbonate, 9.98 g (70.2 mmol, 3.0 equiv.) of sodium sulfate, 0.74 g (11.7 mmol, 0.5 equiv.) of copper powder, and 60 mL of 1,2-dichlorobenzene were added, and the mixed solution was stirred under reflux for 24 hours under a nitrogen atmosphere. Thereafter, the mixture was diluted with toluene and filtered through celite. The filtrate was concentrated and then purified by silica gel column chromatography to obtain Intermediate 2 (amount of 10.7 g, yield of 50%).

### Synthesis of Intermediate 3

In a reaction vessel, 10.7 g (16.1 mmol, 1.0 equiv.) of Intermediate 2, 5.1 g (16.9 mmol, 1.05 equiv.) of 5′-(tert-butyl) [1,1′:3′-1″-terphenyl]-2′-amine, 2.32 g (24.2 mmol, 1.5 equiv.) of sodium tert-butoxide, 0.22 g (0.24 mmol, 0.015 equiv.) of tris(dibenzylideneacetone) dipalladium (0), 0.40 g (0.64 mmol, 0.040 equiv.) of BINAP, and 80 mL of toluene were added, and the mixed solution was stirred under reflux for 6 hours under a nitrogen atmosphere. Thereafter, the mixture was diluted with toluene and filtered through celite, and then, silica gel. The filtrate was concentrated and dispersed in methanol for washing to obtain Intermediate 3 (amount of 12.2 g, yield of 86%).

### Synthesis of Intermediate 4

In a reaction vessel, 12.0 g (13.6 mmol, 1.0 equiv.) of Intermediate 3, 7.87 g (16.3 mmol, 1.2 equiv.) of 3-bromo-5-iodobiphenyl, 5.62 g (40.7 mmol, 3.0 equiv.) of potassium carbonate, 5.78 g (40.7 mmol, 3.0 equiv.) of sodium sulfate, 0.43 g (6.78 mmol, 0.5 equiv.) of copper powder, and 35 mL of 1,2-dichlorobenzene were added, and the mixed solution was stirred under reflux for 24 hours under a nitrogen atmosphere. Thereafter, the mixture was diluted with toluene and filtered through celite. The filtrate was concentrated and then purified by silica gel column chromatography to obtain Intermediate 4 (amount of 10.4 g, yield of 68%).

### Synthesis of Intermediate 5

In a reaction vessel, 5.00 g (4.48 mmol, 1.0 equiv.) of Intermediate 4, 1.67 g (8.96 mmol, 2.1 equiv.) of N-bromosuccinimide, and 100 mL of dichloromethane were added, and the mixed solution was stirred at 0° C. for 3 hours under a nitrogen atmosphere. Thereafter, the mixture was diluted with dichloromethane and washed with a sodium bisulfite solution. The organic phase was water-washed and dried (water removed) using magnesium sulfate. Thereafter, the organic phase was filtered through silica gel, the filtrate was concentrated and dispersed in methanol for washing to obtain Intermediate 5 (amount of 5.42 g and yield of 95%).

### Synthesis of Intermediate 6

In a reaction vessel, 2.00 g (1.57 mmol, 1.0 equiv.) of Intermediate 5, 1.54 g (3.92 mmol, 2.5 equiv.) of boron triiodide, and 15 mL of 1,2-dichlorobenzene were added, and the mixed solution was stirred at 140° C. for 3 hours under a nitrogen atmosphere. Thereafter, the mixture was diluted with dichloromethane and washed with a phosphate buffer solution. The organic phase was washed with a sodium bisulfite solution and water and dried using magnesium sulfate. The organic phase was concentrated and purified by silica gel column chromatography to obtain Intermediate 6 (amount of 0.26 g and yield of 15%).

### Synthesis of Compound 1

In a reaction vessel, 2.50 g (2.22 mmol, 1.0 equiv.) of Intermediate 6 and 25 mL of tetrahydrofuran were added, and the mixed solution was cooled at −70° C. under a nitrogen atmosphere. 3.0 mL (4.89 mmol, 2.2 equiv.) of 1.6 M tert-butyllithiumpentane solution was added and stirred for 1 hour. Afterwards, 0.48 g (2.67 mmol, 1.2 equiv.) of 9-fluorenone was added, and the mixed solution was stirred overnight at room temperature. Next, the solvent was removed by distillation, and 25 mL of dichloromethane and 0.17 mL (2.68 mmol, 2.0 equiv.) of methanesulfonic acid were added and stirred for 3 hours at room temperature. Thereafter, the mixture was diluted with dichloromethane and then washed. The organic phase was water-washed and dried using magnesium sulfate. The dehydrated organic phase was concentrated and purified by silica gel column chromatography to obtain Compound 1 (amount of 0.4 g and yield of 15%).

The structural identification of Compound 1 was performed by liquid chromatography-mass spectrometry (LC/MS). Specifically, the sample (i.e., previously obtained Compound 1) was dissolved in tetrahydrofuran at a concentration of 0.1 mass %, and was subjected to mass spectrometry using an LC/MS meter, 1260 Infinity-Quaternary 6100MS (produced by Agilent Technology Ltd.). The obtained results are as follows: LC-MS: 1207.4 ([M+H]⁺).

### Measurement of Peak Wavelength of Fluorescence

Compound 1 and the following Comparative compound 1 known in the art (below), each at 1×10⁻⁶ M (=mol/dm³, mol/L) in toluene solution, were measured at room temperature using the F-7000 spectrofluorometer (Hitachi High-Tech Ltd.) with an excitation wavelength of 300 nm to evaluate the peak wavelength (nm) of the photoluminescence (PL). The results are shown in Table 1.

TABLE 1

| Compound | λ ^{PL}/nm |
|---|---|
| Compound 1 | 454 |
| Comparative compound 1 | 453 |

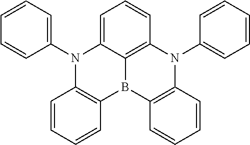 [SMILES: c1ccc(N2c3ccccc3B3c4ccccc4N(c4ccccc4)c4cccc2c43)cc1]

Comparative compound 1

Referring to the results of Table 1, it was confirmed that Compound 1 according to an embodiment exhibited a peak wavelength within the blue wavelength range. Preparation methods of thin film

A 50 nm-thickness thin film (hereinafter, also referred to as a ‘host dispersion film’) was prepared by co-depositing Compound 1 or Comparative compound onto a quartz substrate at a weight ratio of 1 mass % with respect to a host compound under a vacuum of 10⁻⁵ Pa. Here, as the host compound, Compound HT1, Compound HT2, and Phosphorescent Complex Pt1 were used, with the mass ratio of Compound HT1:Compound HT2:Phosphorescent Complex Pt1 set as 60:40:13. Furthermore, the structures of Compound HT1, Compound HT2, and Phosphorescent Complex Pt1 are shown below:

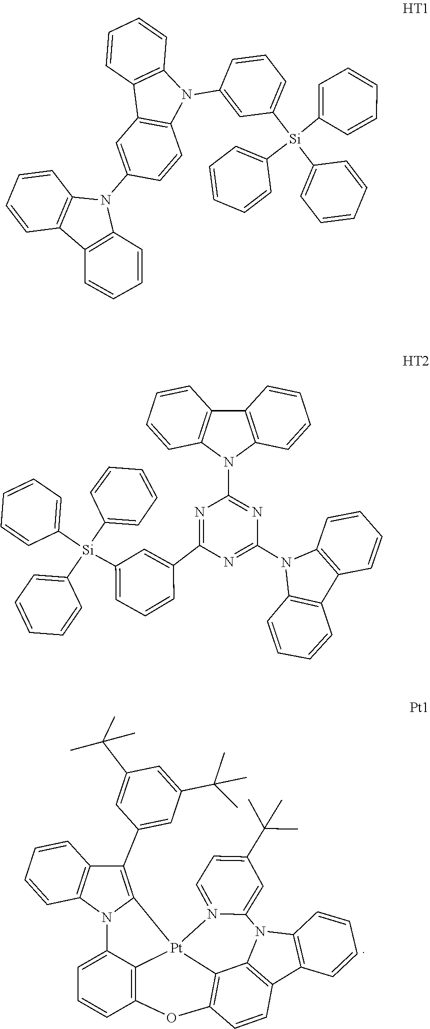

The prepared thin film (i.e., the host dispersion film) was cut into 6 mm wide strips, which were then subjected to PL measurement conducted at room temperature using a F-7000 spectrofluorometer (Hitachi High-Tech Ltd.), The peak wavelength (i.e., maximum emission wavelength) was calculated from the obtained emission spectrum. The PL results are shown in Table 2.

### Measurement of PL Quantum Yield (PLQY)

The prepared thin film (i.e., the host dispersion film) was subjected to PLQY measurement using the Quantaurus-QY® Absolute PL quantum yield spectrometer (C11347-01, Hitach High-Tech Ltd.). During the measurement, the excitation wavelength was scanned in 10 nm intervals from 280 nm to 350 nm, and the excitation wavelength region where the absorption value of the compound has 20% or more of the excitation photointensity was adopted. The PLQY value was set to the highest value within the adopted excitation wavelength region, and the evaluation results are shown in Table 2.

TABLE 2

| Compound | λ^{PL} (nm) | PLQY (%) |
|---|---|---|
| Compound 1 | 454 | 0.80 |
| Comp. compound 1 | 460 | 0.71 |

Referring to the results of Table 2, it was confirmed that Compound 1 according to an embodiment exhibited a peak wavelength within the blue wavelength range. Furthermore, based on a higher PLQY of Compound 1 than Comparative compound 1, Compound 1 exhibited superior agglutination-inhibiting effect, and thus was more suitable as a luminescent dopant.

### Manufacture of Organic Electroluminescent Device 1

An ITO glass substrate with an electrode pattern completely formed was cut to a size of 50 mm×50 mm×0.7 mm, sonicated with acetone, isopropyl alcohol, and pure water in the stated order, for 15 minutes each, and then cleaned by OV ozone for 30 minutes. Then, the following layers were deposited on the ITO electrode (positive electrode) on the glass substrate using a vacuum deposition device.

HAT-CN (see the following formula) was deposited on the ITO electrode to form a hole injection layer having a film thickness of 10 nm. Next, Compound HT3 (see the following formula) was deposited on the hole injection layer to form a hole transport layer having a film thickness of 140 nm. Subsequently, Compound HT1 (see the following formula) was deposited on the hole transport layer to form an electron-blocking layer having a film thickness of 5 nm. As a result, a hole transport region was formed.

On the hole transport region thus formed, Compound HT1, Compound HT2, Phosphorescent Complex Pt1 (see the formula below), and Compound 1 were co-deposited to prepare an emission layer having a film thickness of 4 0 nm. Here, the emission layer was prepared in a way that the mass ratio of Compound HT1, Compound HT2, and Phosphorescent Complex (Compound HT1: Compound HT2: Phosphorescent Complex Pt1) in the emission layer was set to be 60:40:13. Furthermore, the emission layer was prepared in a way that the concentration of Compound 1 in the emission layer was set to be 1.5 mass % with respect to the total mass (i.e., total mass of the emission layer) of Compound HT1, Compound HT2, phosphorescent Complex P1, and Compound 1. Compound HT1 and Compound HT2 may each be a host material.

Compound HT2 was vacuum-deposited on the emission layer to form a hole-blocking layer having a thin thickness of 5 nm. Next, Compound H91 and LiQ were co-deposited at a mass ratio of 5:5 (Compound H91:LiQ=5:5 (unit:mass ratio)) to form an electron transport layer having a film thickness of 30 nm. Next, LiQ was deposited on the electron transport layer to form an electron injection layer having a film thickness of 1 nm. As a result, an electron transport region was formed. An Al (negative electrode) was deposited to the electron injection layer to a film thickness of 100 nm, thereby manufacturing organic electroluminescent device 1.

Afterwards, in a glove box in a nitrogen atmosphere with a moisture concentration of 1 ppm or less and an oxygen concentration of 1 ppm or less, organic electroluminescent device 1 was sealed using a glass seal tube with a desiccant attached and a UV-curable resin (produced by MORESCO Ltd., product name: WB90US). Accordingly, the manufacture of the organic electroluminescent device 1 was completed.

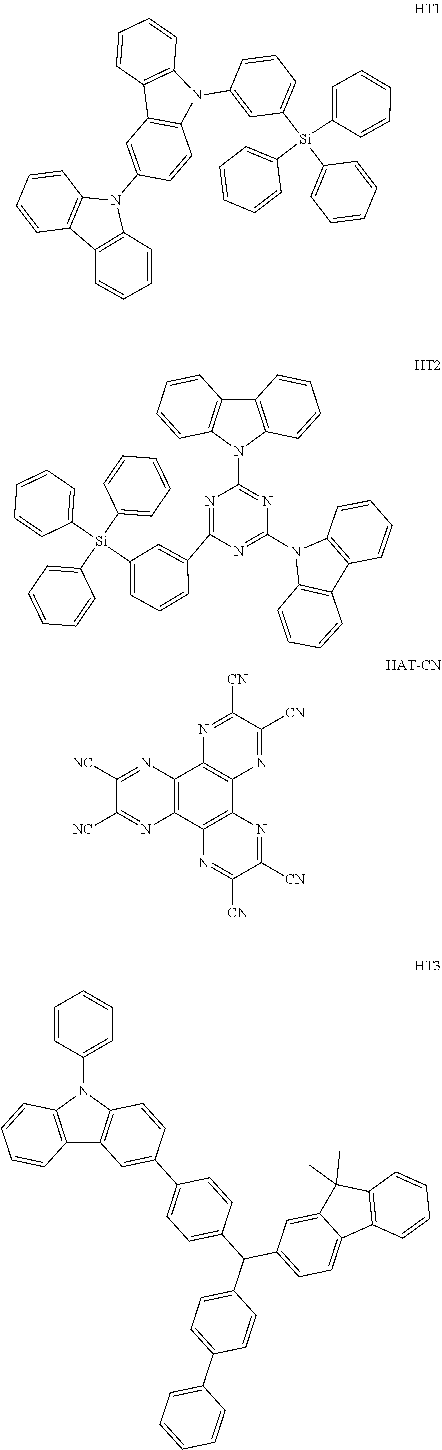 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; N#Cc1nc2c3nc(C#N)c(C#N)nc3c3nc(C#N)c(C#N)nc3c2nc1C#N ; CC1(C)c2ccccc2-c2ccc(C(c3ccc(-c4ccccc4)cc3)c3ccc(-c4ccc5c(c4)c4ccccc4n5-c4ccccc4)cc3)cc21]

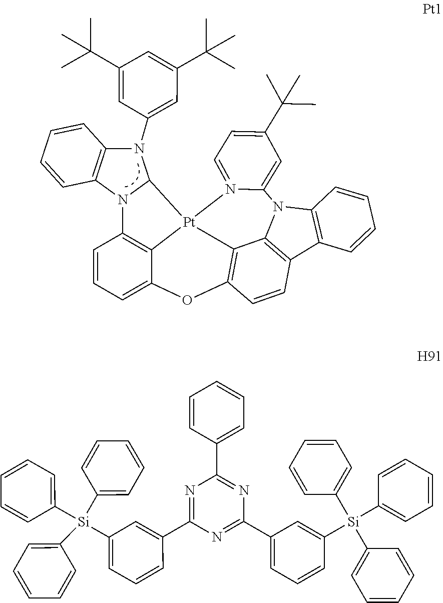

Comparative organic electroluminescent device 1 was manufactured in the same manner as in the manufacture of organic electroluminescent device 1, except that Comparative compound 1 was used instead of Compound 1 in the emission layer.

### Evaluation of Organic Electroluminescent Device

### External Quantum Efficiency and Device Lifespan

The external quantum efficiency and device lifespan were evaluated as follows.

The organic electroluminescent device was induced to emit light by varying the applied voltage using a direct current-constant voltage power supply (source meter model 2400, KEITHLEY Instrument Company). Then, the luminance, emission spectrum, and emission intensity were measured using a luminance meter (SR-3, Topcon).

The external quantum efficiency was calculated from the emission spectrum, luminance, and current value at the time of measurement. The external quantum efficiency at a luminance of 1,000 cd/m² was defined as EQE[%].

The results of the organic electroluminescent device are listed in Table 3. Referring to Table 3, the external quantum efficiency was expressed as a relative value with the EQE of the comparative organic electroluminescent device 1 set to 1.

In addition, the device lifespan (durability) was measured by defining LT70 as the time required for the luminance, which attenuates over time when continuously driven at the current value with the initial luminance of 1,000 cd/m, to reach 70% of the initial luminance. Furthermore, LT70 in Table 3 is expressed as a relative value with LT70 (unit:hr) of comparative organic electroluminescent device 1 set as 1.

TABLE 3

| | | External quantum | |
|---|---|---|---|
| | | efficiency | LT70 |
| Organic EL device 1 | Compound 1 | 1.3 | 5.8 |
| Comp. organic EL | Comparative | 1.0 | 1.0 |
| device 1 | compound 1 | | |

Referring to the results of Table 3, organic electroluminescent device 1 using compound 1 as the compound represented by Formula 1 exhibited high EQE compared to comparative organic electroluminescent device 1 using Comparative compound 1, demonstrating that organic electroluminescent device 1 using compound 1 had improved luminescence efficiency and long device lifespan.

According to the one or more embodiments, a composition for an organic electroluminescent device may have improved characteristics in terms of efficiency, lifespan, and/or color purity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition for an organic electroluminescent device, the composition comprising a compound represented by Formula 1 and a phosphorescent material: 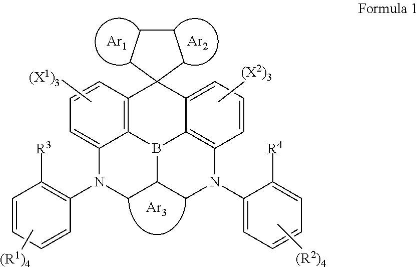
wherein, in Formula 1,
Ar₁, Ar₂, and Ars are each independently a substituted or unsubstituted aryl group or a substituted or unsubstituted heteroaryl group,
X¹ and X² are each independently hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group,
R¹ and R² are each independently hydrogen, deuterium, a substituted or unsubstituted alkyl group, a substituted or unsubstituted aryl group, a substituted or unsubstituted heteroaryl group, or a substituted or unsubstituted cycloalkyl group, and
R³ and R⁴ are each independently a substituted or unsubstituted alkyl group having at least three carbon atoms, a substituted or unsubstituted aryl group, a substituted or unsubstituted heteroaryl group, or a substituted or unsubstituted cycloalkyl group.

2. The composition of claim 1, wherein Ar₁, Ar₂ and Ars are each independently a substituted or unsubstituted aryl group.

3. The composition of claim 1, wherein
X¹ and X² are each independently hydrogen, an unsubstituted alkyl group, an unsubstituted aryl group, or an unsubstituted heteroaryl group, and
R¹ and R² are each independently hydrogen, deuterium, an unsubstituted alkyl group, or an unsubstituted aryl group.

4. The composition of claim 1, wherein R³ and R⁴ are each independently an unsubstituted alkyl group having at least 3 carbon atoms, a substituted or unsubstituted aryl group, or an unsubstituted cycloalkyl group.

5. The composition of claim 1, wherein the compound represented by Formula 1 is a compound represented by Formula 2: 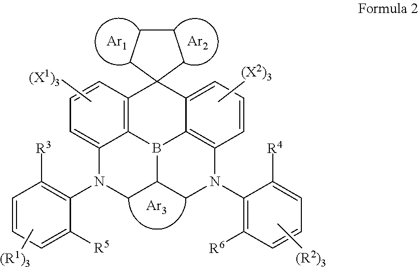
wherein, in Formula 2,
R⁵ and R⁶ are each independently a substituted or unsubstituted alkyl group having at least three carbon atoms, a substituted or unsubstituted aryl group, a substituted or unsubstituted heteroaryl group, or a substituted or unsubstituted cycloalkyl group.

6. The composition of claim 5, wherein R⁵ and R⁶ are each independently an unsubstituted aryl group or an unsubstituted cycloalkyl group.

7. The composition of claim 1, wherein Ar₁, Ar₂ and Ars are each an unsubstituted phenyl group.

8. The composition of claim 5, wherein
X¹ and X² are each independently hydrogen, a tert-butyl group, a phenyl group, a carbazolyl group, a 4-tert-butylphenyl group, or a 3,5-di(tert-butyl)phenyl group,
R¹ and R² are each independently hydrogen, a tert-butyl group, an isopropyl group, or a phenyl group,
R⁵ and R⁶ are each independently an isopropyl group, a tert-butyl group, or a phenyl group, and
R³ and R⁴ are each independently an isopropyl group, a tert-butyl group, a phenyl group, a substituted phenyl group, or a cyclohexyl group.

9. The composition of claim 1, wherein the compound represented by Formula 1 is selected from Group I:

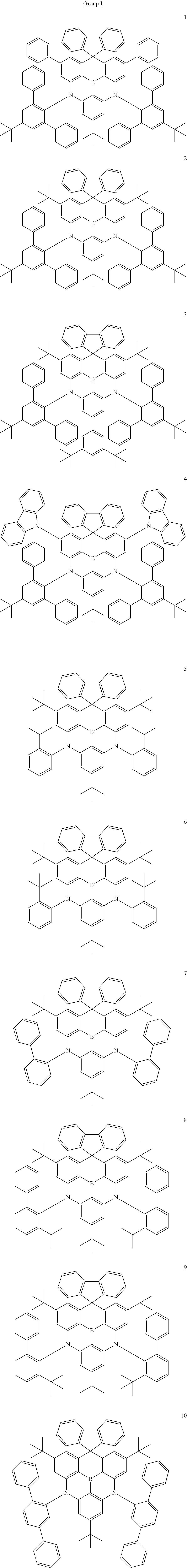

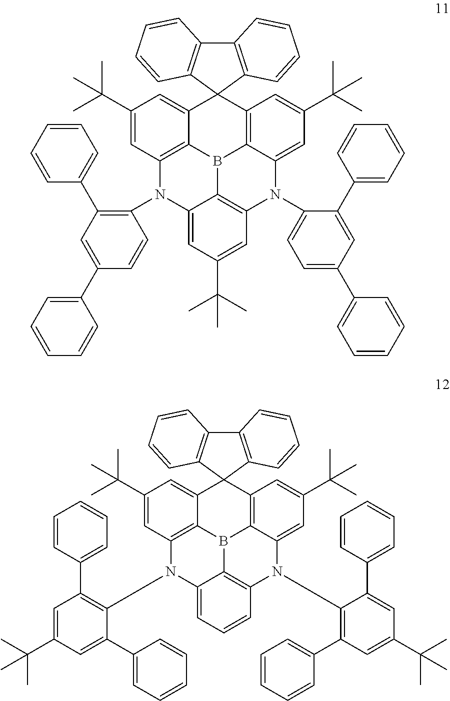 [SMILES: CC(C)(C)c1cc2c3c(c1)N(c1ccc(-c4ccccc4)cc1-c1ccccc1)c1cc(C(C)(C)C)cc4c1B3c1c(cc(C(C)(C)C)cc1C41c3ccccc3-c3ccccc31)N2c1ccc(-c2ccccc2)cc1-c1ccccc1 ; CC(C)(C)c1cc(-c2ccccc2)c(N2c3cccc4c3B3c5c2cc(C(C)(C)C)cc5C2(c5ccccc5-c5ccccc52)c2cc(C(C)(C)C)cc(c23)N4c2c(-c3ccccc3)cc(C(C)(C)C)cc2-c2ccccc2)c(-c2ccccc2)c1]

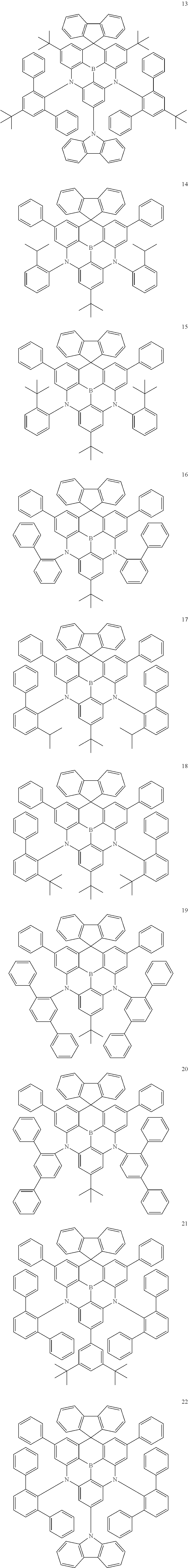

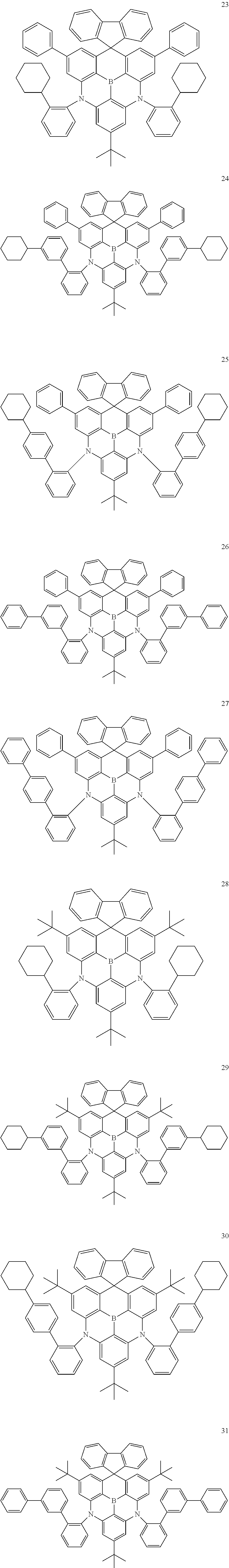

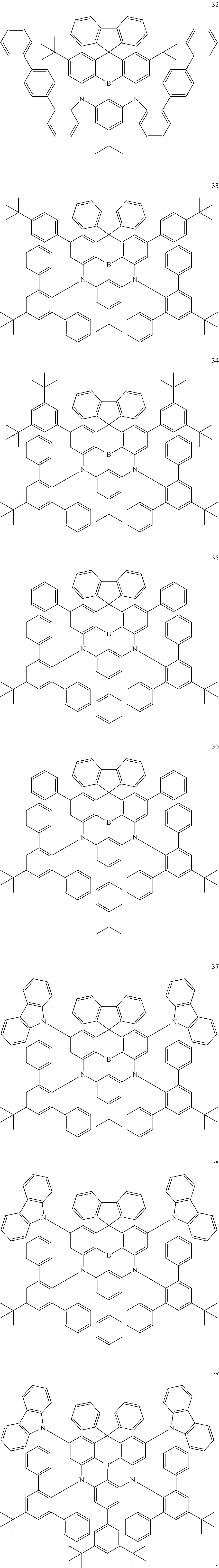

10. The composition of claim 1, wherein the phosphorescent material is an iridium complex or a platinum complex.

11. The composition of claim 1, wherein the phosphorescent material is present in a range of about 100 parts by mass to about 10000 parts by mass, with respect to 100 parts by mass of the compound represented by Formula 1.

12. A compound represented by Formula 1: 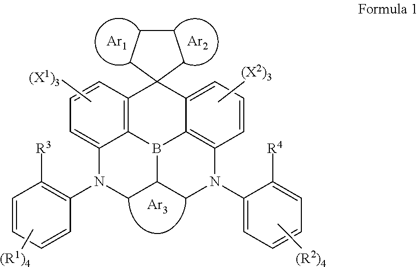
wherein, in Formula 1,
Ar₁, Ar₂, and Ars are each independently a substituted or unsubstituted aryl group or a substituted or unsubstituted heteroaryl group,
X¹ and X² are each independently hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group,
R¹ and R² are each independently hydrogen, deuterium, a substituted or unsubstituted alkyl group, a substituted or unsubstituted aryl group, a substituted or unsubstituted heteroaryl group, or a substituted or unsubstituted cycloalkyl group, and
R³ and R⁴ are each independently a substituted or unsubstituted alkyl group having at least three carbon atoms, a substituted or unsubstituted aryl group, a substituted or unsubstituted heteroaryl group, or a substituted or unsubstituted cycloalkyl group.

13. An organic electroluminescent device comprising: a first electrode; a second electrode; and an organic layer arranged between the first electrode and the second electrode, the organic layer including an emission layer,
wherein the organic electroluminescent device comprises a composition for an organic electroluminescent device, the composition comprising a compound represented by Formula 1 and a phosphorescent material: 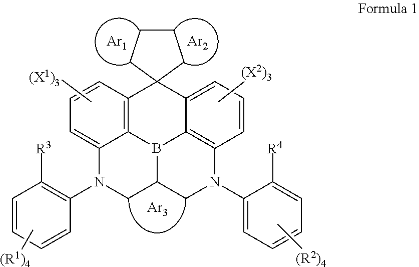
wherein, in Formula 1,
Ar₁, Ar₂, and Ars are each independently a substituted or unsubstituted aryl group or a substituted or unsubstituted heteroaryl group,
X¹ and X² are each independently hydrogen, deuterium, a substituted or unsubstituted alkyl group, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted cycloalkyl group, a substituted or unsubstituted aryloxy group, a substituted or unsubstituted heteroaryloxy group, a substituted or unsubstituted arylthio group, or a substituted or unsubstituted heteroarylthio group,
R¹ and R² are each independently hydrogen, deuterium, a substituted or unsubstituted alkyl group, a substituted or unsubstituted aryl group, a substituted or unsubstituted heteroaryl group, or a substituted or unsubstituted cycloalkyl group, and
R³ and R⁴ are each independently a substituted or unsubstituted alkyl group having at least three carbon atoms, a substituted or unsubstituted aryl group, a substituted or unsubstituted heteroaryl group, or a substituted or unsubstituted cycloalkyl group.

14. The organic electroluminescent device of claim 13, wherein
the organic electroluminescent device emits light with a peak wavelength region in a range of about 360 nm to about 515 nm, and
a half-width at half maximum of 30 nm or less.

15. The organic electroluminescent device of claim 13, wherein the composition is arranged in the emission layer.

16. The organic electroluminescent device of claim 15, wherein
the emission layer comprises a host, the compound of Formula 1, and the phosphorescent material,
wherein the host and the compound of Formula 1 are different, and the host and the phosphorescent material are different.

17. The organic electroluminescent device of claim 16, wherein the host does not emit light, and the compound of Formula 1 emits light.

18. The organic electroluminescent device of claim 15, wherein the compound of Formula 1 is present in the emission layer in a range of about 0.05 mass % to about 50 mass %.

19. The organic electroluminescent device of claim 15, wherein the phosphorescent material is present in the emission layer is in a range of about 0.1 mass % to about 50 mass %.

20. An electronic apparatus comprising the organic electroluminescent device of claim 13.
